(19) United States
(12) Patent Application Publication
(10) Pub. No.: US 2008/0258138 A1
(43) Pub. Date: Oct. 23, 2008

(54) Thin film transistor array panel and fabricating method thereof, and flat panel display with the same

(75) Inventors: Keun-Kyu Song, Yongin-si (KR); Seung-Hwan Cho, Hwaseong-si (KR); Jung-Hun Noh, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 12/148,909

(22) Filed: Apr. 23, 2008

(30) Foreign Application Priority Data
Apr. 23, 2007 (KR) 10-2007-0039415
Aug. 31, 2007 (KR) 10-2007-0088268

(51) Int. Cl. H01L 51/05; H01L 51/40; H01L 29/786; H01L 21/336

(52) U.S. Cl. 257/40; 438/99; 257/347; 438/158; 257/E51.007; 257/E29.273; 257/E21.411

(57) ABSTRACT

An organic thin film transistor array panel, for an embodiment, includes a plurality of pixel electrodes formed on a top layer to cover organic thin film transistors, with display areas defined by the areas of the pixel electrodes. Accordingly, the aperture ratio of the display device may be increased. A ratio of width to length (W/L) in a channel of an organic thin film transistor may be increased, and thereby on current (Ion) of the organic thin film transistor may be increased. The organic semiconductor may be prevented from overflowing while being formed in holes by an inkjet printing method such that deterioration of thin film transistor characteristics and pixel defects is prevented. The adhesive of the electrophoretic sheet is prevented from penetrating into the organic semiconductor when the electrophoretic display is formed by attaching the electrophoretic sheet to the organic thin film transistor array panel by a lamination method.

### CROSS-REFERENCE TO RELATED APPLICATION

This application claims priority to and the benefit of Korean Patent Application Nos. 10-2007-0039415 and 10-2007-0088268 filed in the Korean Intellectual Property Office on Apr. 23, 2007 and Aug. 31, 2007, respectively, the entire contents of which are incorporated herein by reference.

### BACKGROUND

(a) Technical Field

Embodiments of the present invention relate generally to an organic thin film transistor array panel and a flat panel display including the organic thin film transistor array panel.

(b) Description of the Related Art

A thin display device that is driven with a low voltage and is substantially flat is referred to as a flat panel display. The flat panel display includes a liquid crystal display, an electrophoretic display, etc. The flat panel display includes a plurality of pairs of field generating electrodes and an electro-optical active layer interposed therebetween.

One electrode of each pair of field generating electrodes is commonly connected to a switching element supplied with an electrical signal, and the electro-optical active layer converts the electrical signals to optical signals to display images.

Thin film transistors having three terminals are used as the switching elements in a flat panel display, and the flat panel display also includes gate lines for transmitting gate signals to control the thin film transistors and data lines for transmitting signals to be applied to the pixel electrodes.

Among thin film transistors, organic thin film transistors using an organic semiconductor instead of an inorganic semiconductor, such as silicon (Si), have been vigorously researched.

Here, the organic semiconductor is commonly electrically connected to the source electrode and the drain electrode of the thin film transistor.

The organic thin film transistor may be fabricated by a solution process such as inkjet printing, and therefore the organic thin film transistor may be easily applied to a large-sized flat panel display.

Moreover, since an organic thin film transistor may be fabricated in the form of a fiber or a film due to the flexible characteristics of the organic material, it has been in the spotlight as a core element of a flexible display device.

A structure such as a bank is used for fabricating the organic thin film transistor array panel using the solution process such as inkjet printing.

Accordingly, a display device such as the liquid crystal display or the electrophoretic display including the organic thin film transistor array panel has the bank such that an aperture ratio of the display device is reduced by as much as the area of the bank.

On the other hand, if a bank having a small area is formed for improving the aperture ratio of the display device, the organic semiconductor material may overflow during the solution process such as inkjet printing such that the characteristics of the organic thin film transistors may be deteriorated and pixel defects may occur.

In addition, if a bank having a small area is formed for improving the aperture ratio of the display device, a ratio of width to length (W/L) in a channel of the organic thin film transistor may be reduced. Accordingly, an “on” current (Ion) of the organic thin film transistor may be reduced such that the characteristics of the organic thin film transistors may be deteriorated.

If the organic thin film transistor is used for the electrophoretic display and electrophoretic particles are formed by a lamination method on the organic thin film transistor, an adhesive material may penetrate the organic semiconductor such that the characteristics of the organic thin film transistor may be deteriorated.

Meanwhile, it is not easy to form an organic semiconductor having fine patterns by using inkjet printing due to the inkjet printing equipment. Accordingly, a method in which a bank having a hole is formed in the thin film transistor array panel and then ink including the organic semiconductor is selectively placed in the hole by inkjet printing, which is commonly used.

Exemplarily, plasma treatment is used to adjust contact angles that are different from each other within the hole of the bank and outside the hole of the bank when materials within the hole of the bank and outside the hole of the bank are the same. Otherwise, the side of the hole may be formed by using a different material to that of the remaining part of the bank such that contact angles are adjusted to be different from each other. However, a suitable material for adjusting the contact angles has not been developed.

Note that the above information disclosed in this Background section is only for enhancement of understanding of the background of the invention and therefore may contain information that would not necessarily be prior art or known in this country to a person of ordinary skill in the art.

### SUMMARY

Systems and methods are disclosed, in accordance with one or more embodiments, to provide an organic thin film transistor array panel and a flat panel display including the thin film transistor array panel having advantages of improving characteristics of a thin film transistor and aperture ratio of the flat panel display.

Methods are disclosed, in accordance with one or more embodiments, to provide a manufacturing method of a thin film transistor array panel and a flat panel display including the thin film transistor array panel having advantages of forming a pattern of a semiconductor accurately and having no channel damage.

A thin film transistor array panel according to an embodiment of the present invention includes: a substrate; a gate line formed on the substrate, extending in a first direction, and including a gate electrode; a storage electrode line formed on the substrate; a gate insulation layer covering the gate line and the storage electrode line; a data line formed on the gate insulation layer, extending in a second direction to cross the gate line, and including a source electrode; a drain electrode separated from the data line and facing the source electrode; a bank having a first hole exposing the source electrode and the drain electrode; an organic semiconductor formed in the first hole and connected to the source electrode and the drain electrode; a passivation layer covering the bank and the organic semiconductor; and a pixel electrode formed on the passivation layer and connected to the drain electrode.

The pixel electrode may partially overlap the organic semiconductor, the bank, the source electrode, and the drain electrode.

The gate electrode may extend in a second direction, and the length L1 of the gate electrode may satisfy the relationship to the interval G1 between the gate line and the storage electrode line 131 as follows: 0.2 G1<L1<G1.

The size (the length in first direction×the length in the second direction) of the first hole of the bank may be one of about 50 μm×50 μm, about 60 μm×80 μm, about 80 μm×80 μm, and about 100 μm×200 μm.

The source electrodes may include a linear portion and an extension portion extending in the second direction from an end of the linear portion.

The drain electrode may include a first linear portion extending in the first direction, a second linear portion extending in the second direction from the end of the first linear portion, a third linear portion extending toward the source electrode in the first direction from a middle portion of the second linear portion, and an extension portion extending in the second direction from the end of the third linear portion to be opposite to the source electrode.

The storage electrode line may extend in the first direction and include a storage electrode extending in the second direction, and the first linear portion of the drain electrode may overlap the storage electrode line and the second linear portion of the drain electrode may overlap the storage electrode.

The pixel electrode may be connected to the drain electrode through a second hole of the bank that exposes an end portion of the third linear portion of the drain electrode, and may be made of an opaque metal.

The distance between the first hole and the second hole may be about 70 μm or more, and the distance between two adjacent first holes of the bank may be about 100 μm or more.

The data line may include a first layer made of a transparent conductive oxide and a second layer made of a low resistivity metal, and the source electrode and the drain electrode may include a first layer made of a transparent conductive oxide.

The data line may include a first layer made of a transparent conductive oxide and a second layer made of a low resistivity metal, and portions of the source electrode and the drain electrode contacting the organic semiconductor may include a first layer made of a transparent conductive oxide.

The passivation layer may have a double-layered structure including a lower passivation layer made of a non-photosensitive insulating material and an upper passivation layer made of a photosensitive insulating material and disposed on the lower passivation layer.

A manufacturing method for a thin film transistor array panel according to an embodiment of the present invention includes: forming a gate line and a storage electrode line parallel to the gate line on a substrate; forming a gate insulation layer on the gate line, the storage electrode line, and the substrate; forming a data line, a source electrode, and a drain electrode on the gate insulation layer; forming a bank having a first hole and a second hole on the gate insulation layer, the data line, the source electrode, and the drain electrode; forming an organic semiconductor in the first hole of the bank; forming a passivation layer having a hole aligned with the second hole of the bank on the bank and the organic semiconductor; and forming a pixel electrode on the passivation layer.

The forming of the organic semiconductor may be performed by inkjet printing.

The forming of the passivation layer may include depositing a non-photosensitive insulating layer, depositing a photosensitive insulating layer on the non-photosensitive insulation layer, patterning the photosensitive insulating layer by photolithography, and etching the non-photosensitive insulating layer by using the patterned photosensitive insulation layer as an etching mask.

The forming of the data line, the source electrode, and the drain electrode may include: sequentially depositing a lower conducting layer such as ITO (indium tin oxide) and an upper conducting layer such as molybdenum; coating a photosensitive layer on the upper metal layer and exposing and developing the coated photosensitive layer to form a first photosensitive layer pattern; etching the upper conducting layer and the lower conducting layer by using the first photosensitive layer pattern as an etching mask to remove the upper conducting layer and the lower conducting layer except the data line, the source electrode, and the drain electrode; ashing the first photosensitive layer pattern to form a second photosensitive layer pattern; and etching the upper conducting layer by using the second photosensitive layer pattern as an etching mask to remove the upper conducting layer of portions of the source electrode and the drain electrode.

The forming of the data line, the source electrode, and the drain electrode may include: sequentially depositing a lower conducting layer such as ITO and an upper conducting layer such as molybdenum; patterning the upper conducting layer and the lower conducting layer to the data line, the source electrode, and the drain electrode including the upper conducting layer and the lower conducting layer; forming a bank having a first hole and a second hole on the gate insulation layer, the data line, the source electrode, and the drain electrode; and etching the upper conducting layer by using the bank as an etching mask to remove the upper conducting layer of the source electrode and the drain electrode disposed in the first hole and expose the lower conducting layer of the source electrode and the drain electrode disposed in the first hole.

A contact hole exposing an end portion of the gate line may be formed in the gate insulation layer during the forming of the gate insulation layer, and contact assistants contacting an end portion of the gate line through the contact hole may be formed during the forming of the data line, the source electrode, and the drain electrode.

A thin film transistor array panel according to another embodiment of the present invention includes: a substrate, a gate line formed on the substrate, extending in a first direction, and including a gate electrode; a gate insulation layer formed on the gate line and containing fluorine in a portion thereof; a data line formed on the gate insulation layer, extending in a second direction to cross the gate line, and including a source electrode; a drain electrode separated from the data line and facing the source electrode; a bank including a first hole exposing the source electrode and the drain electrode and disposed on the source electrode and the drain electrode; a semiconductor formed in the first hole and connected to the source electrode and the drain electrode to form a channel of a thin film transistor; a passivation layer covering the bank and the semiconductor; and a pixel electrode formed on the passivation layer and connected to the drain electrode.

The portion of the gate insulation layer containing the fluorine may have a ring planar shape formed along with the inner edge of the first hole.

The bank may contain the fluorine by being subjected to a plasma treatment

The gate insulation layer may include an organic insulator.

The data line may include a lower layer including a transparent conductive oxide and an upper layer including a metal, portions of the source electrode and drain electrode disposed in the first hole may be composed of the lower layer, and remaining portions of the source electrode and drain electrode may be composed of the upper layer.

The thin film transistor array panel may further include contact assistants formed on the gate insulation layer, contacting an end portion of the gate line through a contact hole, and composed of the lower layer, the data line may include an end portion having a large area and composed of the lower layer, and the portion of the gate insulation layer containing the fluorine may further include a peripheral area of the end portion of the data line.

The first hole may have a smaller area than that of the gate electrode and be disposed over the gate electrode.

The pixel electrode may cover the semiconductor.

A manufacturing method for a thin film transistor array panel according to another embodiment of the present invention includes A) forming a gate line including a gate electrode on a substrate, B) forming a gate insulation layer on the gate line and the substrate, C) sequentially depositing a first conductive layer and a second conductive layer on the gate insulation layer, D) patterning the first conductive layer and the second conductive layer to form a data line, a source electrode, and a drain electrode composed of the first conductive layer and the second conductive layer, and a block portion disposed over the gate electrode, connected to the source electrode and the drain electrode, and composed of the first conductive layer, E) forming a bank having a first hole exposing the source electrode, the drain electrode, and the block portion, F) performing fluorine plasma treatment on the bank, G) etching the first conductive layer by using the second conductive layer exposed through the first hole as an etching mask to remove the block portion, H) forming a semiconductor in the first hole, I) forming a passivation layer on the bank and the semiconductor, and J) forming a pixel electrode on the passivation layer.

The forming of the semiconductor may be performed by dripping a semiconductor material into the first hole by inkjet printing.

The step of D) may include D-1) coating a photosensitive layer on the second conductive layer and exposing and developing the coated photosensitive layer by using a halftone mask to form a first photosensitive layer pattern, D-2) etching the first conductive layer and the second conductive layer by using the first photosensitive layer pattern as an etching mask to form a data pattern composed of the first conductive layer and the second conductive layer and including the data line, the source electrode, the drain electrode, and a connection portion between the source electrode and the drain electrode, D-3) etching back the first photosensitive layer pattern to form a second photosensitive layer pattern, D-4) etching the second conductive layer by using the second photosensitive layer pattern as an etching mask to remove the second photosensitive layer of the connection portion between the source electrode and the drain electrode, and D-5) removing the second photosensitive layer pattern.

The first conductive layer and the second conductive layer disposed over the gate electrode may have a smaller size than that of the gate electrode in the step of D-2)

The first hole may have a smaller size than that of the gate electrode and a larger size than that of the first conductive layer and the second conductive layer disposed over the gate electrode, and the first hole may be disposed over the gate electrode in the step of E).

The step of E) may include forming a second hole exposing a portion of the drain electrode, the step of I) may include forming a hole aligned with the second hole, and the pixel electrode may be connected to the drain electrode through the second hole and the hole.

The manufacturing method may further include G-1) etching the second conductive layer by using the bank as an etching mask to remove the second conductive layer exposed through the first hole between the step of G) and the step of H).

The step of D) may include forming contact assistants including the first conductive layer and the second conductive layer and connected to an end portion of the gate line, and the step of G-1) may include removing the second conductive layer of the contact assistants.

A flat panel display according to another embodiment of the present invention includes the organic thin film transistor array panel described above, a common electrode panel facing the organic thin film transistor array panel, and electrophoretic particles disposed between the organic thin film transistor array panel and the common electrode panel.

### BRIEF DESCRIPTION OF THE DRAWINGS

The above and other features and advantages of embodiments of the present invention will become apparent by describing in detail with reference to the attached drawings in which:

FIG. 1 is a layout view of an organic thin film transistor array panel according to an embodiment of the present invention;

FIG. 2 is a sectional view of the organic thin film transistor array panel shown in FIG. 1 taken along the line II-II;

FIG. 3, FIG. 5, FIG. 7, and FIG. 9 are layout views of the organic thin film transistor array panel shown in FIG. 1 and FIG. 2 in intermediate steps of a manufacturing method thereof according to an embodiment of the present invention;

FIG. 4 is a sectional view of the organic thin film transistor array panel shown in FIG. 3 taken along the line IV-IV;

FIG. 6 is a sectional view of the organic thin film transistor array panel shown in FIG. 5 taken along the line VI-VI;

FIG. 8 is a sectional view of the organic thin film transistor array panel shown in FIG. 7 taken along the line VIII-VIII;

FIG. 10 is a sectional view of the organic thin film transistor array panel shown in FIG. 9 taken along the line X-X;

FIG. 11 is a sectional view of the organic thin film transistor array panel according to another embodiment of the present invention taken along the line II-II shown in FIG. 1;

FIG. 12 to FIG. 17 are sectional views of the organic thin film transistor array panel shown in FIG. 1 and FIG. 11 in intermediate steps of a manufacturing method thereof according to an embodiment of the present invention;

FIG. 18 is a sectional view of an electrophoretic display including the organic thin film transistor array panel shown in FIG. 1 and FIG. 2;

FIG. 19 and FIG. 20 are graphs representing characteristics of a thin film transistor in an organic thin film transistor array panel, in which the organic thin film transistor is not covered by a pixel electrode, before/after an electrophoretic particle layer is attached to the thin film transistor array panel.

FIG. 21 is a graph representing characteristics of a thin film transistor in an organic thin film transistor array panel according to an embodiment of the present invention before/after an electrophoretic particle layer is attached to the thin film transistor array panel.

FIG. 22 is a layout view of an organic thin film transistor array panel according to another embodiment of the present invention;

FIG. 23 is a sectional view of the organic thin film transistor array panel shown in FIG. 22 taken along the lines XXIII-XXIII and XXIII′-XXIII′;

FIG. 24, FIG. 26, FIG. 28, FIG. 30, and FIG. 32 are layout views of the organic thin film transistor array panel shown in FIG. 22 and FIG. 23 in intermediate steps of a manufacturing method thereof according to another embodiment of the present invention;

FIG. 25 is a sectional view of the organic thin film transistor array panel shown in FIG. 24 taken along the lines XXV-XXV and XXV′-XXV′;

FIG. 27 is a sectional view of the organic thin film transistor array panel shown in FIG. 26 taken along the lines XXVII-XXVII and XXVII′-XXVII′;

FIG. 29 is a sectional view of the organic thin film transistor array panel shown in FIG. 28 taken along the lines XXIX-XXIX and XXIX′-XXIX′;

FIG. 31 is a sectional view of the organic thin film transistor array panel shown in FIG. 30 taken along the lines XXXI-XXXI and XXXI′-XXXI′;

FIG. 33 is a sectional view of the organic thin film transistor array panel shown in FIG. 32 taken along the lines XXXIII-XXXIII and XXXIII′-XXIII′;

FIG. 34 is a sectional view of the organic thin film transistor array panel shown in FIG. 33 after the next processes;

FIG. 35 is a sectional view of the organic thin film transistor array panel shown in FIG. 26 to FIG. 29 for representing the manufacturing method;

FIG. 36 is table representing contact angle and pattern accuracy according to a fluorine plasma treatment;

FIG. 37 is a sectional view of an electrophoretic display including the organic thin film transistor array panel according to an embodiment of the present invention;

FIG. 38 shows graphs representing characteristics of a thin film transistor in an organic thin film transistor array panel, in which the organic thin film transistor is not covered by a pixel electrode, before/after an electrophoretic particle layer is attached to the thin film transistor array panel.

FIG. 39 is a graph representing characteristics of a thin film transistor in an organic thin film transistor array panel according to an embodiment of the present invention before/after an electrophoretic particle layer is attached to the thin film transistor array panel.

### DESCRIPTION OF REFERENCE NUMERALS INDICATING PRIMARY ELEMENTS IN THE DRAWINGS

| | |
|---|---|
| 110: insulation substrate | 121: gate line |
| 124: gate electrode | 124a: connection portion |
| 124b: electrode portion | 131: storage electrode line |
| 140: gate insulation layer | 146: bank |
| 147: first hole | 148: second hole |
| 154: organic semiconductor | 171: data line |
| 173: source electrode | 175: drain electrode |
| 180: passivation layer | 191: pixel electrode |
| 220: black matrix | 230: electrophoretic particle |
| 240: adhesive | 270: common electrode |

### DETAILED DESCRIPTION

Embodiments of the present invention will be described more fully hereinafter with reference to the accompanying drawings. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, region, or substrate is referred to as being “on” another element, it can be directly on the other element or intervening elements may also be present. In contrast, when an element is referred to as being “directly on” another element, there are no intervening elements present.

### Exemplary Embodiment 1

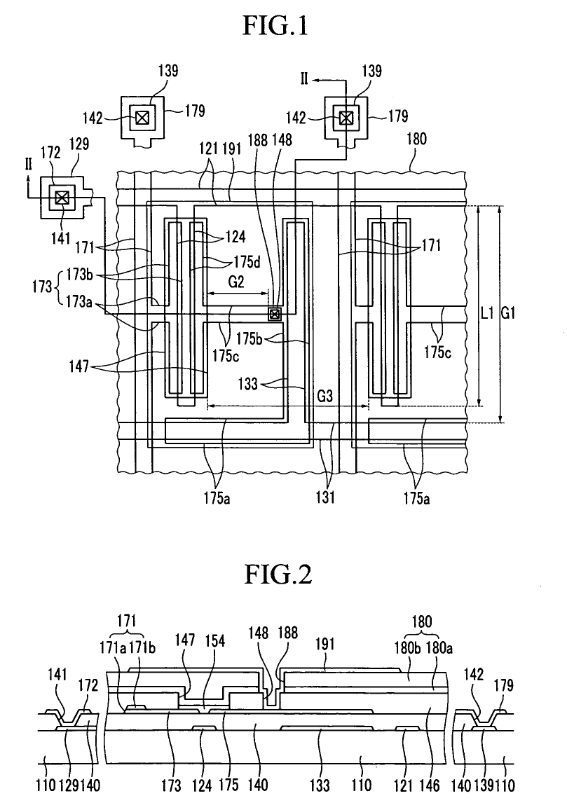

An organic thin film transistor array panel according to an embodiment of the present invention will be described in detail with reference to FIG. 1 and FIG. 2.

FIG. 1 is a layout view of an organic thin film transistor array panel according to an embodiment of the present invention, and FIG. 2 is a sectional view of the organic thin film transistor array panel shown in FIG. 1 taken along the line II-II.

A plurality of gate lines 121, a plurality of storage electrode lines 131, and a plurality of data pads 139 are formed on an insulating substrate 110 made of a material such as transparent glass, silicone, or plastic.

The gate lines 121 transmit gate signals and extend substantially in a first direction (a transverse direction shown in FIG. 1). Each gate line 121 includes a plurality of gate electrodes 124 projecting in a second direction (a longitudinal direction shown in FIG. 1).

Each gate line 121 includes an end portion 129 having a large area for contact with another layer or an external driving circuit.

A gate driving circuit (not shown) for generating the gate signals may be mounted on a flexible printed circuit (FPC) film (not shown), which may be attached to the substrate 110, directly mounted on the substrate 110, or integrated with the substrate 110. The gate lines 121 may extend to be connected to a driving circuit that may be integrated with the substrate 110.

The length L1 of each gate electrode 124 satisfies the relation to the interval G1 between the gate line 121 and the storage electrode line 131 as follows: 0.2G1<L1<G1.

Here, the length L1 of each gate electrode 124 may be preferably elongated within the condition that the length L1 of each gate electrode 124 is not longer than the interval G1 between the gate line 121 and the storage electrode line 131. Accordingly, the length L1 of each gate electrode 124 may be long and a ratio of width to length (W/L) in a channel of an organic thin film transistor including the gate electrode 124 may be increased.

Thereby, an on current (Ion) of the organic thin film transistor may be increased such that the characteristics of the organic thin film transistors may be improved.

The storage electrode lines 131 are supplied with a predetermined voltage and extend substantially parallel to the gate lines 121. Each of the storage electrode lines 131 is disposed between two adjacent gate lines 121. Each of the storage electrode lines 131 includes a plurality of storage electrodes 133 extending upward. The storage electrodes 133 are substantially parallel to the gate electrodes 124.

The data pads 139 are connected to end portions 179 of data lines 171 described later, and they are island types. The data pads 139 may be omitted.

The gate lines 121, the storage electrode lines 131, and the data pads 139 are preferably made of an Al-containing metal such as Al and an Al alloy, a Ag-containing metal such as Ag and a Ag alloy, a Cu-containing metal such as Cu and a Cu alloy, a Mo-containing metal such as Mo and a Mo alloy, Cr, Ta, Ti, and W.

However, they may have a multi-layered structure including two conductive films (not shown) having different physical characteristics. For example, the gate lines 121 and the storage electrode lines 131 may have a double-layered structure including a conductive oxide layer such as ITO (indium tin oxide) and IZO (indium zinc oxide), and a low resistivity metal conductive layer.

A gate insulating layer 140 having a plurality of holes 141 and 142 exposing the end portions 129 of the gate lines 121 and the data pads 139, respectively, are formed on the substrate 110, the gate lines 121, and the storage electrode lines 131. The gate insulation layer 140 may be made of an inorganic insulator or an organic insulator.

Examples of the inorganic insulator include silicon nitride and silicon oxide that may have their surface treated with octadecyl-trichloro-silane (OTS). Examples of the organic insulator include hydrocarbon-based polymers including fluorine and parylene that can be deposited by chemical vapor deposition (CVD) under vacuum.

A plurality of data lines 171, a plurality of drain electrodes 175, and a plurality of contact assistants 172 are formed on the gate insulation layer 140.

The data lines 171 transmit data signals and extend substantially in a longitudinal direction to intersect the gate lines 121 and the storage electrodes lines 131.

Each of the data lines 171 includes a plurality of source electrodes 173 and an end portion 179 having a large area for contact with another layer or an external driving circuit. Each of the source electrodes 173 includes a linear portion 173a and an extension portion 173b extending in the second direction from an end of the linear portion 173a. The extension portion 173b partially overlaps the gate electrode 124.

A data driving circuit (not shown) for generating the data signals may be mounted on a flexible printed circuit (FPC) film (not shown), which may be attached to the substrate 110, directly mounted on the substrate 110, or integrated with the substrate 110. The data lines 121 may extend to be connected to a driving circuit that may be integrated with the substrate 110.

Each of the drain electrodes 175 is an island type, and includes a first linear portion 175a overlapping the storage electrode line 131, a second linear portion 175b extending in the second direction from the end of the first linear portion 175a and overlapping the storage electrode 133, a third linear portion 175c extending toward the gate electrode 124 in the first direction from a middle portion of the second linear portion 175b, and an extension portion 175d extending in the second direction from the end of the third linear portion 175c.

The first linear portion 175a and the second linear portion 175b of the drain electrode 175 overlap the storage electrode line 131 and the storage electrode 133 to enhance the voltage storing capacity of a storage capacitor.

The extension portion 175d of the drain electrode 175 is parallel to the extension portion 173b of the source electrode 173 and partially overlaps the gate electrode 124.

The extension portion 173b of the source electrode 173 and the extension portion 175d of the drain electrode 175 may be preferably elongated within the condition that the lengths of the extension portions 173b and 175d are not longer than the length L1 of each gate electrode 124.

Accordingly, a ratio of width to length (W/L) in a channel of an organic thin film transistor including the source electrode 173 and the drain electrode 175 may be increased, and thereby the characteristics of the organic thin film transistors may be improved.

The data lines 171 may have a multi-layered structure including two conductive layers 171a and 171b having different physical properties from each other.

The lower layer 171a may be preferably made of a transparent conductive oxide such as ITO (indium tin oxide) and IZO (indium zinc oxide).

The upper layer 171b may be preferably made of low resistivity metal such as an Al-containing metal, a Ag-containing metal, a Au-containing metal, a Cu-containing metal, a Mo-containing metal, Cr, Ta, and Ti.

Here, the upper layer 171b is removed in the end portions 179 of the data lines 171 to expose the lower layer 171a. Accordingly, the end portions 179 of the data lines 171 may be made of a transparent conductive oxide such as ITO (indium tin oxide) and IZO (indium zinc oxide).

The source electrodes 173, the drain electrodes 175, and the contact assistants 172 may preferably be made of a transparent conductive oxide such as ITO (indium tin oxide) and IZO (indium zinc oxide).

A bank 146 is formed on the substrate 110 having the data lines 171 and the drain electrodes 175.

The bank 146 has a plurality of first holes 147 exposing portions of the extension portions 173b of the source electrodes 173 and portions of the extension portions 175d of the drain electrodes 175, and in which the extension portions 173b of the source electrodes 173 and the extension portions 175d of the drain electrodes 175 are opposite to each other. The bank 146 has a plurality of second holes 148 exposing the end portions of the third linear portions 175c of the drain electrodes 175.

Here, each of the first holes 147 of the bank 146 has an elongated planar shape in the second direction (the vertical direction shown in FIG. 1), i.e., the first holes 147 may have a longer length in the second direction than that in the first direction.

Even though the first holes 147 are shown to have a rectangle planar shape in FIG. 1, the first holes 147 may have an elongated oval planar shape.

Even though not shown, the first holes 147 may have a square or circular planar shape.

The size (the length in first direction×the length in the second direction) of the first hole 147 may be one of about 50 μm×50 μm, about 60 μm×80 μm, about 80 μm×80 μm, and about 100 μm×200 μm.

A plurality of organic semiconductor islands 154 are formed on the source electrodes 173, the drain electrodes 175, and the gate insulating layer 140 in the first holes 147, respectively. The organic semiconductor islands 154 may have the same planar size as that of the first holes 147. The organic semiconductor islands 154 are disposed on the gate electrodes 124, and contact the source electrodes 173 and the drain electrodes 175 in the first holes 147.

The organic semiconductor islands 154 may be an oligomer or polymer having a structure in which electrons may easily move, such as a conjugated system.

The organic semiconductor islands 154 may include a high molecular compound or a low molecular compound that is soluble in an aqueous solution or an organic solvent The organic semiconductor islands 154 may be made of polythienylenevinylene, poly 3-hexylthiophene, polythiophene, phthalocyanine, metallized phthalocyanine, or their halogenated derivatives; of perylenetetracarboxylic dianhydride (PTCDA), naphthalenetetracarboxylic dianhydride (NTCDA), or their imide derivatives; or of perylene, coronene, or derivatives thereof with a substituent.

A gate electrode 124, a source electrode 173, and a drain electrode 175 along with an organic semiconductor island 154 form a thin film transistor having a channel formed in the organic semiconductor island 154 disposed between the source electrode 173 and the drain electrode 175.

The organic semiconductor islands 154 may be imprinted in the first holes 147 by an inkjet printing method. As described above, the first holes 147 may have a larger size than the sizes indicated above.

Accordingly, the organic semiconductor island 154 may be prevented from overflowing from the first holes 147 while imprinting the organic semiconductor in the first holes 147 by an inkjet printing method.

In an experiment according to an embodiment of the present invention, the organic semiconductor may overflow from a hole having a size of 50 μm×50 μm while imprinting the organic semiconductor in the hole by using the known inkjet printing method. On the other hand, the organic semiconductor may not overflow from a hole having a size of 100 μm×200 μm.

Accordingly, the first holes 147 are preferably formed to have an elongated planar shape in the second direction.

If the first hole 147 has a small planar size, for example 50 μm×50 μm, the distance G2 between the first hole 147 and the second hole 148 may be about 70 μm or more for preventing the overflowing organic semiconductor from filling the second holes 148 in the embodiment of the present invention. In addition, the distance G3 between two adjacent first holes 147 of the bank 146 may be about 100 μm or more.

Accordingly, a ratio of width to length (W/L) in a channel of the organic thin film transistors including the organic semiconductor islands 154 formed in the first holes 147 may be increased, and the deterioration of characteristics of the organic thin film transistors and pixel defects occurring in the formation of the organic semiconductors 154 by an inkjet printing method may be prevented in the embodiment of the present invention.

A passivation layer 180 is formed on the bank 146 and the organic semiconductors 154. The passivation layer 180 has a double-layered structure including a lower passivation layer 180a and an upper passivation layer 180b. The lower passivation layer 180a may be made of a non-photosensitive insulating material and the upper passivation layer 180b may be made of a photosensitive insulating material and disposed on the lower passivation layer 180a. The upper passivation layer 180b may be thicker than the lower passivation layer 180a.

The passivation layer 180 has a plurality of contact holes 188 communicating with the second holes 148 of the bank 146. Here, the upper passivation layer 180b may be thicker than the lower passivation layer 180a and the thicker upper passivation layer 180b may be used as an etching mask during etching of the lower passivation layer 180a such that the patterning of the lower passivation layer 180a by dry etching may be performed effectively, when the upper passivation layer 180b and the lower passivation layer 180a are dry-etched for forming the contact holes 188.

In the present embodiment, the passivation layer 180 covers the organic semiconductor islands 154 such that the organic semiconductor islands 154 may be prevented from being damaged in method processes such as the dry etching of the passivation layer 180.

A plurality of pixel electrodes 191 are formed on the passivation layer 180. The pixel electrodes 191 are connected to the drain electrodes 175 through the contact holes 148 and 188, and receive data voltages from the drain electrodes 175 of the thin film transistors. The pixel electrodes 191 may be made of an opaque metal material. However, the pixel electrodes 191 may be made of a transparent conductive oxide layer such as ITO (indium tin oxide) and IZO (indium zinc oxide).

The pixel electrodes 191 supplied with the data voltages generate electric fields in cooperation with a common electrode (not shown) of an opposing display panel (not shown) supplied with a common voltage, which drive an electro-optical active layer such as electrophoretic particle layer (not shown) interposed therebetween.

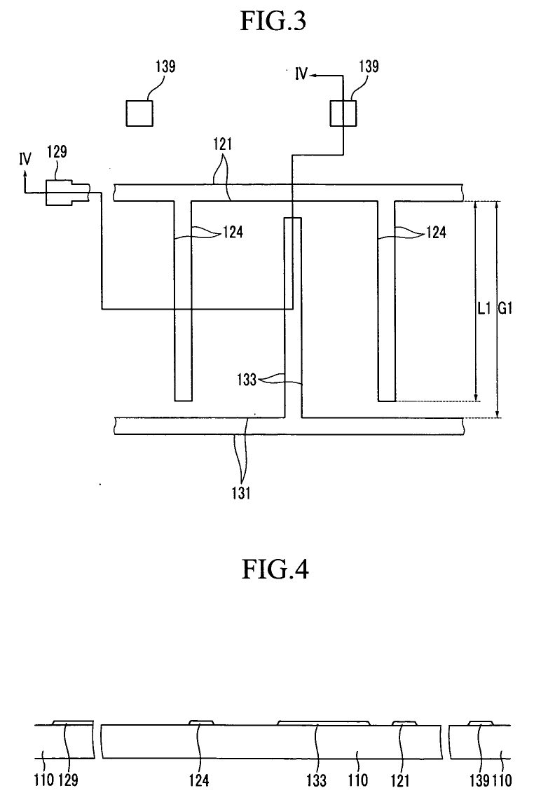

Now, a manufacturing method of the organic thin film transistor array panel shown in FIG. 1 and FIG. 2 will be described in detail with reference to FIG. 3 to FIG. 10.

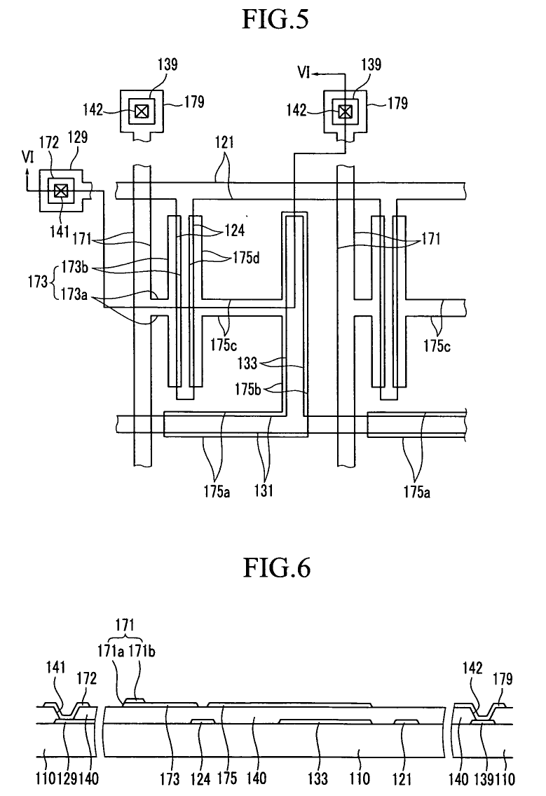

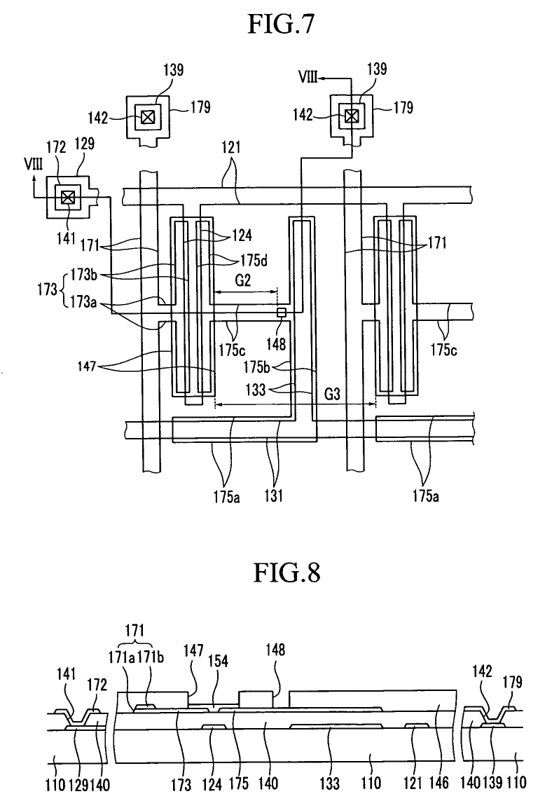

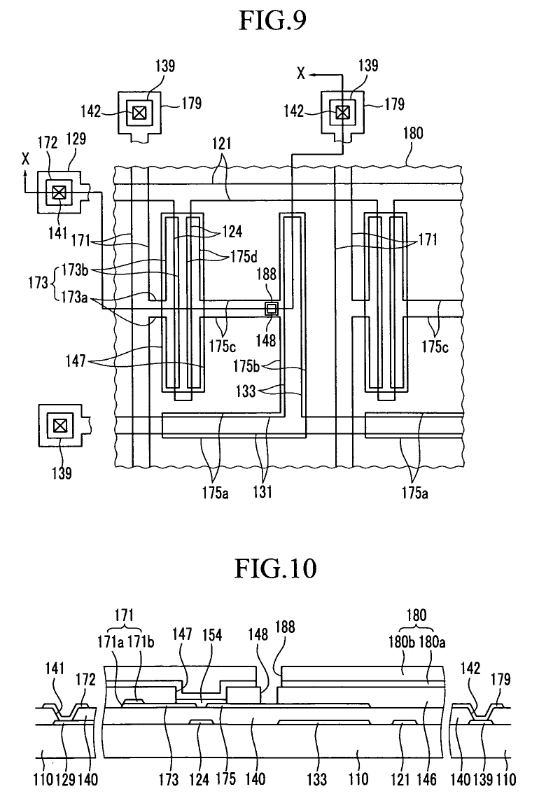

FIG. 3, FIG. 5, FIG. 7, and FIG. 9 are layout views of the organic thin film transistor array panel shown in FIG. 1 and FIG. 2 in intermediate steps of a manufacturing method thereof according to an embodiment of the present invention. FIG. 4 is a sectional view of the organic thin film transistor array panel shown in FIG. 3 taken along the line IV-IV, FIG. 6 is a sectional view of the organic thin film transistor array panel shown in FIG. 5 taken along the line VI-VI, FIG. 8 is a sectional view of the organic thin film transistor array panel shown in FIG. 7 taken along the line VIII-VIII, and FIG. 10 is a sectional view of the organic thin film transistor array panel shown in FIG. 9 taken along the line X-X.

First, a gate metal layer such as aluminum and molybdenum is deposited on a substrate 110 and patterned by photolithography and etching to form a plurality of gate lines 121 including a plurality of gate electrodes 124 and end portions 129, a plurality of storage electrode lines 131 including a plurality of storage electrodes 133, and a plurality of data pads 139, as shown in FIG. 3 and FIG. 4.

Here, the length L1 of each gate electrode 124 satisfies the relation to the interval G1 between the gate line 121 and the storage electrode line 131 as follows: 0.2G1<L1<G1.

In addition, the length L1 of each gate electrode 124 may be preferably elongated within the condition that the length L1 of each gate electrode 124 is not longer than the interval G1 between the gate line 121 and the storage electrode line 131 such that the length L1 of each gate electrode 124 may be long and a ratio of width to length (W/L) in a channel of an organic thin film transistor including the gate electrode 124 may be increased.

Referring to FIG. 5 and FIG. 6, an insulating layer is deposited on the substrate 110, the gate lines 121, and the storage electrode lines 131, and a plurality of data pads 139 and the insulating layer are patterned by photolithography and etching to form a gate insulation layer 140 having a plurality of contact holes exposing the end portions 129 of the gate lines 121 and the data pads 139, respectively.

Next, a lower conducting layer made of a transparent conductive material such as ITO and an upper conducting layer made of a metal such as molybdenum are sequentially deposited on the substrate 110 and the gate insulating layer 140, and are patterned by photolithography and etching to form a plurality of data lines 171 including a lower conductive layer 171a and an upper conductive layer 171b, and a plurality of source electrodes 173, a plurality of drain electrodes 175, a plurality of contact assistants 172, and a plurality of end portions 179 of the data lines 171 composed of the lower conductive layer 171a.

Here, a half-tone mask may be used to form the data lines 171 including the lower conductive layer 171a and the upper conductive layer 171b, and the source electrodes 173, the drain electrodes 175, the contact assistants 172, and the end portions 179 of the data lines 171 composed of the lower conductive layer 171a simultaneously.

Now, the formation of the data lines 171, the drain electrodes 175, and the contact assistants 172 will be described in more detail.

The half-tone mask is divided into light transmitting transparent areas, translucent areas, and light blocking opaque areas.

First, a lower conducting layer made of a transparent conductive material such as ITO and an upper conducting layer made of a metal such as molybdenum are sequentially deposited on the substrate 110 and the insulating layer 140, and then a photosensitive layer is coated on the upper conducting layer. Next, the photosensitive layer is exposed through the half-tone mask and then the exposed photosensitive layer is developed.

The developed photosensitive layer has a position-dependent thickness such that the photosensitive layer located in the light transmitting transparent area is eliminated, that located in the translucent areas is reduced, and that located in the light blocking opaque areas is not eliminated. The photosensitive layer located on the data lines 171 except the end portions 179 is thick, the photosensitive layer located on the source electrodes 173, the drain electrodes 175, the contact assistants 172, and the end portions 179 of the data lines 171 is thin, and the photosensitive layer located on the remaining portions is removed.

The upper conducting layer and the lower conducting layer are etched by using the developed photosensitive layer having a position-dependent thickness as an etching mask to form the data lines 171, the drain electrodes 175, and the contact assistants 172 including the lower conducting layer and the upper conducting layer.

Next, ashing is performed on the photosensitive layer having a position-dependent thickness such that the photosensitive layer disposed in the translucent areas is all eliminated and the thickness of the photosensitive layer disposed in light blocking opaque areas become thin.

Then, the upper conducting layer is etched using the remaining photosensitive layer disposed in the light blocking opaque areas as an etching mask to form the source electrodes 173, the drain electrodes 175, the contact assistants 172, and the end portions 179 of the data lines 171 composed of the lower conductive layer.

Referring to FIG. 7 and FIG. 8, an organic insulator is coated and patterned by photolithography and etching to form a bank 146 having a plurality of first holes 147 and a plurality of second holes 148 exposing portions of the electrodes 173 and the drain electrodes 175 and exposing the end portions of the drain electrodes 175.

Here, when the organic insulator has photosensitivity, the bank 146 may be formed by photolithography.

The distance G2 between the first hole 147 and the second hole 148 may be about 70 μm or more for preventing organic semiconductor islands 154 imprinted in the first hole 147 from overflowing from the first hole 147 and filling the second hole 148.

In addition, the distance G3 between two adjacent first holes 147 of the bank 146 may be about 100 μm or more.

Next, an organic semiconductor solution is imprinted in the first holes 147 of the bank 146 by an inkjet printing method and dried to form a plurality of organic semiconductor islands 154.

Here, the organic semiconductor islands 154 are formed in the first holes 147 of the bank 146 such that the organic semiconductor islands 154 may have substantially the same planar size as that of the first holes 147. The organic semiconductor islands 154 are disposed on the gate electrodes 124, and contact the source electrodes 173 and the drain electrodes 175 in the first holes 147.

Referring to FIG. 9 and FIG. 10, a lower passivation layer 180a of a non-photosensitive insulating layer and an upper passivation layer 180b of a photosensitive insulating layer are sequentially deposited on the bank 146 and the organic semiconductors 154. Then the upper passivation layer 180b is patterned by photolithography and the lower passivation layer 180a is dry-etched using the patterned upper passivation layer 180b as an etching mask to form the passivation layer 180 having a plurality of contact holes 188 communicating with the second holes 148 of the bank 146.

Here, the upper passivation layer 180b may be thicker than the lower passivation layer 180a because the upper passivation layer 180b is used for an etching mask during the dry-etching of the lower passivation layer 180a.

Finally, an opaque metal layer such as chromium is deposited on the passivation layer 180 and patterned by photolithography and etching to form a plurality of pixel electrodes 191 connected to the drain electrodes 175 through the second holes 148 and 188, as shown in FIG. 1 and FIG. 2.

### Exemplary Embodiment 2

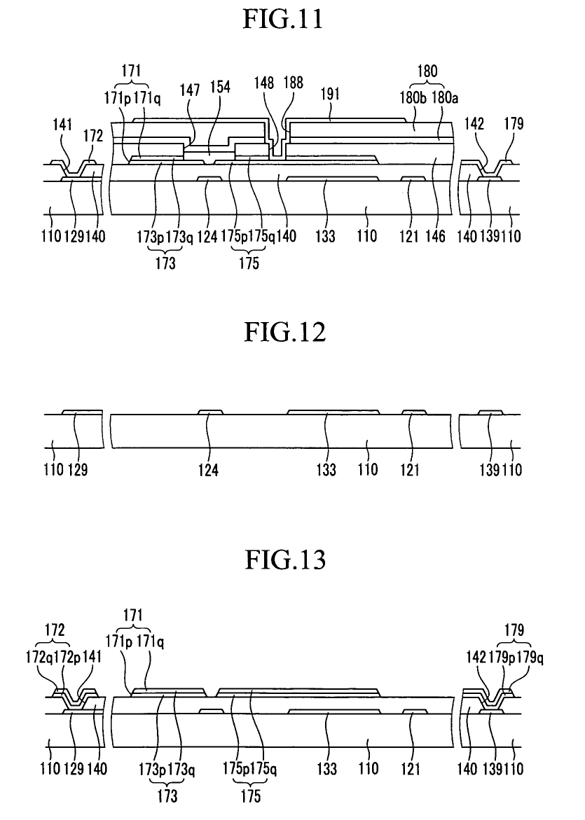

An organic thin film transistor array panel according to another embodiment of the present invention will be described in detail with reference to FIG. 1 and FIG. 11. FIG. 11 is a sectional view of the organic thin film transistor array panel according to another embodiment of the present invention taken along the line II-II shown in FIG. 1.

As shown in FIG. 1 and FIG. 11, a layered structure of an organic thin film transistor array panel according to the present embodiment is substantially the same as that shown in FIG. 1 and FIG. 2.

A plurality of gate lines 121, a plurality of storage electrode lines 131, and a plurality of data pads 139 are formed on an insulating substrate 110. Each gate line 121 includes a plurality of gate electrodes 124 and an end portion 129 having a large area, each of the storage electrode lines 131 includes a plurality of storage electrodes 133 extending toward the gate line 121, and the data pads 139 are connected to end portions 179 of data lines 171 described later, are island types, and may be omitted. Here, the length L1 of each gate electrode 124 may be preferably elongated within the condition that the length L1 of each gate electrode 124 is not longer than the interval G1 between the gate line 121 and the storage electrode line 131. Accordingly, the length L1 of each gate electrode 124 may be long and a ratio of width to length (W/L) in a channel of an organic than film transistor including the gate electrode 124 may be increased.

A gate insulating layer 140 having a plurality of holes 141 and 142 exposing the end portions 129 of the gate lines 121 and the data pads 139, respectively, are formed on the substrate 110, the gate lines 121, and the storage electrode lines 131. A plurality of data lines 171 including a plurality of source electrodes 173 and a plurality of end portions 179, a plurality of drain electrodes 175, and a plurality of contact assistants 172 are formed on the gate insulation layer 140. Each of the source electrodes 173 includes a linear portion 173a and an extension portion 173b extending in the second direction from an end of the linear portion 173a. The extension portion 173b partially overlaps the gate electrode 124. Each of the drain electrodes 175 is an island type, and includes a first linear portion 175a overlapping the storage electrode line 131, a second linear portion 175b extending in the second direction from the end of the first linear portion 175a and overlapping the storage electrode 133, a third linear portion 175c extending toward the gate electrode 124 in the first direction from a middle portion of the second linear portion 175b, and an extension portion 175d extending in the second direction from the end of the third linear portion 175c. The first linear portion 175a and the second linear portion 175b of the drain electrode 175 overlap the storage electrode line 131 and the storage electrode 133 to enhance the voltage storing capacity of a storage capacitor. The extension portion 175d of the drain electrode 175 is parallel to the extension portion 173b of the source electrode 173 and partially overlaps the gate electrode 124. The extension portion 173b of the source electrode 173 and the extension portion 175d of the drain electrode 175 may be preferably elongated within the condition that the lengths of the extension portions 173b and 175d are not longer than the length L1 of each gate electrode 124. Accordingly, a ratio of width to length (W/L) in a channel of an organic thin film transistor including the source electrode 173 and the drain electrode 175 may be increased, and thereby the characteristics of the organic thin film transistors may be improved.

A bank 146 is formed on the substrate 110 having the data lines 171 and the drain electrodes 175. The bank 146 has a plurality of first holes 147 exposing portions of the extension portions 173b of the source electrodes 173 and portions of the extension portions 175d of the drain electrodes 175, and in which the extension portions 173b of the source electrodes 173 and the extension portions 175d of the drain electrodes 175 are opposite to each other. The bank 146 has a plurality of second holes 148 exposing the end portions of the third linear portions 175c of the drain electrodes 175. Here, each of the first holes 147 of the bank 146 has an elongated planar shape in the second direction (the vertical direction shown in FIG. 1), i.e., the first holes 147 may have a longer length in the second direction than in the first direction. The size (the length in first direction×the length in the second direction) of the first hole 147 may be one of about 50 μm×50 μm, about 60 μm×80 μm, about 80 μm×80 μm, and about 100 μm×200 μm.

A plurality of organic semiconductor islands 154 are formed on the source electrodes 173, the drain electrodes 175, and the gate insulating layer 140 in the first holes 147, respectively. The organic semiconductor islands 154 may have the same planar size as that of the first holes 147. The organic semiconductor islands 154 are disposed on the gate electrodes 124, and contact the source electrodes 173 and the drain electrodes 175 in the first holes 147. Here, the distance G2 between the first hole 147 and the second hole 148 may be about 70 μm or more for preventing organic semiconductor islands 154 imprinted in the first hole 147 from overflowing from the first hole 147 and filling a second hole 148. In addition, the distance G3 between two adjacent first holes 147 of the bank 146 may be about 100 μm or more.

Accordingly, a ratio of width to length (W/L) in a channel of the organic thin film transistors including the organic semiconductor islands 154 formed in the first hole 147 may be increased, and the deterioration of characteristics of the organic thin film transistor and pixel defects occurring by the formation of the organic semiconductor islands 154 by an inkjet printing method may be prevented in the embodiment of the present invention.

A passivation layer 180 is formed on the bank 146 and the organic semiconductors 154. The passivation layer 180 has a double-layered structure including a lower passivation layer 180a and an upper passivation layer 180b. The lower passivation layer 180a may be made of a non-photosensitive insulating material and the upper passivation layer 180b may be made of a photosensitive insulating material and disposed on the lower passivation layer 180a. The upper passivation layer 180b may be thicker than the lower passivation layer 180a.

A plurality of pixel electrodes 191 are formed on the passivation layer 180. The pixel electrodes 191 are connected to the drain electrodes 175 through the contact holes 148 and 188, and may be made of an opaque metal material. However, the pixel electrodes 191 may be made of a transparent conductive oxide layer such as ITO (indium tin oxide) and IZO (indium zinc oxide).

However, unlike the organic thin film transistor array panel shown in FIG. 1 and FIG. 2, the data lines 171 and the drain electrodes 175 have a double-layered structure including two conductive layers 171p, 175p and 171q, 175q having different physical properties from each other except for the end portions 179 of the data lines 171 and portions disposed in the first holes 147 and the second holes 148 of the bank 146. In FIG. 11, for the data lines 171 and the drain electrodes 175, the lower and upper layers thereof are denoted by additional characters p and q, respectively.

The lower layer 171p may be preferably made of a transparent conductive oxide such as ITO (indium tin oxide) and IZO (indium zinc oxide), the upper layer 171q may be preferably made of a low resistivity metal such as an Al-containing metal, a Ag-containing metal, a Au-containing metal, a Cu-containing metal, a Mo-containing metal, Cr, Ta, and Ti. Here, the upper layer 171q is removed at the end portions 179 of the data lines 171 to expose the lower layer 179p. Accordingly, the end portions 179 of the data lines 171 may be made of a transparent conductive oxide. In addition, the contact assistants 172 may be preferably made of a transparent conductive oxide such as ITO (indium tin oxide) and IZO (indium zinc oxide).

The upper layers 171q and 175q of the data lines 171 and the drain electrodes 175 are removed in the first holes 147 and the second holes 148 of the bank 146. Accordingly, the organic semiconductor islands 154 are connected to the lower layers 173p and 175p of the source electrodes 173 of the data lines 171 and the drain electrodes 175, and the lower layers 173p and 175p are made of ITO (indium tin oxide) or IZO (indium zinc oxide) having a large work function such that considerable charge may be supplied through the organic semiconductor islands 154. In addition, the data lines 171 and the drain electrodes 175 include the upper layers 171q and 175q having a high conductive property in the remaining portions in which the data lines 171 and drain electrodes 175 are not contacted to the organic semiconductor islands 154 such that data lines 171 having a high conductive property may be realized.

Many characteristics of the organic thin film transistor array panel shown in FIG. 1 and FIG. 2 can be applied to the organic thin film transistor array panel shown in FIG. 1 and FIG. 11.

Now, a manufacturing method of the organic thin film transistor array panel shown in FIG. 1 and FIG. 11 will be described in detail with reference to FIG. 12 to FIG. 17. FIG. 12 to FIG. 17 are sectional views of the organic thin film transistor array panel shown in FIG. 1 and FIG. 11 in intermediate steps of a manufacturing method thereof according to an embodiment of the present invention.

Referring to FIG. 12, a gate metal layer made of a material such as aluminum and molybdenum is deposited on a substrate 110 and patterned by photolithography and etching to form a plurality of gate lines 121 including a plurality of gate electrodes 124 and end portions 129, a plurality of storage electrode lines 131 including a plurality of storage electrodes 133, and a plurality of data pads 139. Here, the length L1 of each gate electrode 124 satisfies the relation to the interval G1 between the gate line 121 and the storage electrode line 131 as follows: 0.2G1<L1<G1.

Next, a gate insulation layer 140 having a plurality of contact holes exposing the end portions 129 of the gate lines 121 and the data pads 139, respectively, is formed on the substrate 110, the gate lines 121, the storage electrode lines 131, and the data pads 139, and then a lower conducting layer made of a transparent conductive material such as ITO and an upper conducting layer made of a metal such as molybdenum are sequentially deposited on the substrate 110 and the gate insulating layer 140, and patterned by photolithography and etching to form a plurality of data lines 171 induding a plurality of source electrodes 173 and a plurality of end portions 179, a plurality of drain electrodes 175, and a plurality of contact assistants 172, as shown in FIG. 13. Here, the data lines 171 and the drain electrodes 175 include a lower layer 171p, 173p, 179p, and 175p and an upper layer 171q, 173q, 179q, and 175q and the contact assistants 172 include lower and upper layers 172p and 172q.

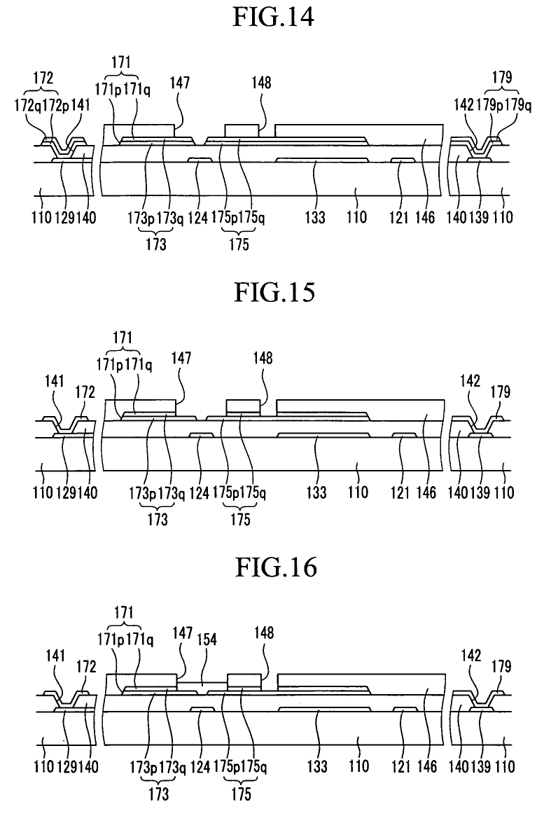

Next, an organic insulator is coated and patterned by photolithography and etching to form a bank 146 having a plurality of first holes 147 and a plurality of second holes 148 exposing portions of the electrodes 173 and the drain electrodes 175 opposite to each other and exposing the end portions of the drain electrodes 175, as shown in FIG. 14. Here, when the organic insulator has photosensitivity, the bank 146 may be formed by photolithography. Here, the distance G2 between the first hole 147 and the second hole 148 may be about 70 μm or more for preventing organic semiconductor islands 154 imprinted in the first hole 147 from overflowing from the first hole 147 and filling a second hole 148. In addition, the distance G3 between two adjacent first holes 147 of the bank 146 may be about 100 μm or more.

Next, the upper layers 171q, 175q, and 172q of the data lines 171, the drain electrodes 175, and the contact assistants 172 are etched by using the bank 146 as an etching mask to remove the upper layers 171q, 175q, and 172q such that the end portions 179 of the data lines 171 and the contact assistants 172 are formed as the lower layer made of ITO (indium tin oxide) or IZO (indium zinc oxide), and the portions of the source electrodes 173 and the drain electrodes 175 exposed through the first holes 147 and the second holes 148 are formed as the lower layer made of ITO (indium tin oxide) or IZO (indium zinc oxide), as shown in FIG. 15.

Next, an organic semiconductor solution is imprinted in the first holes 147 of the bank 146 by an inkjet printing method and dried to form a plurality of organic semiconductor islands 154.

Here, the organic semiconductor islands 154 are formed in the first holes 147 of the bank 146 such that the organic semiconductor islands 154 may have substantially the same planar size as that of the first holes 147. The organic semiconductor islands 154 are disposed on the gate electrodes 124, and contact the source electrodes 173 and the drain electrodes 175 in the first holes 147.

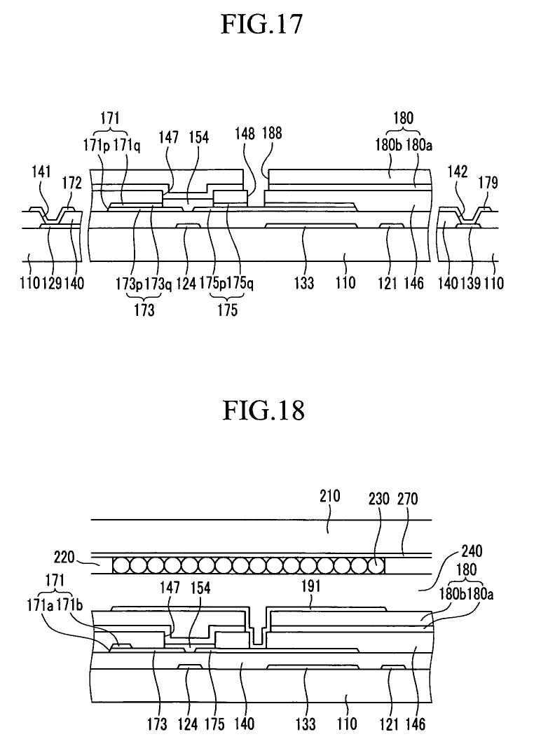

Referring to FIG. 17, a lower passivation layer 180a of a non-photosensitive insulating layer and an upper passivation layer 180b of a photosensitive insulating layer are sequentially deposited on the bank 146 and the organic semiconductors 154. Then the upper passivation layer 180b is patterned by photolithography and the lower passivation layer 180a is dry-etched using the upper passivation layer 180b as an etching mask to form the passivation layer 180 having a plurality of contact holes 188 communicating with the second holes 148 of the bank 146. Here, the upper passivation layer 180b may be thicker than the lower passivation layer 180a because the upper passivation layer 180b is used for an etching mask during the dry-etching of the lower passivation layer 180a.

Finally, an opaque metal layer such as chromium is deposited on the passivation layer 180 and patterned by photolithography and etching to form a plurality of pixel electrodes 191 connected to the drain electrodes 175 through the second holes 148 and 188 as shown in FIG. 11.

As described above, in the organic thin film transistor array panel according to the present embodiment of the invention, the organic semiconductor islands 154 are connected to the lower layers 173p and 175p of the source electrodes 173 of the data lines 171 and the drain electrodes 175, and the lower layers 173p and 175p are made of ITO (indium tin oxide) or IZO (indium zinc oxide) having a large work function such that considerable charge may be supplied through the organic semiconductor islands 154. In addition, the data lines 171 and the drain electrodes 175 include the upper layer 171q and 175q having a high conductive property in the remaining portions in which the data lines 171 and drain electrodes 175 are not contacted to the organic semiconductor islands 154, such that data lines 171 having a high conductive property may be realized.

### Exemplary Embodiment 3

Now, a flat panel display including a thin film transistor array panel according to an embodiment of the present invention will be described in detail with reference to FIG. 18. FIG. 18 is a sectional view of an electrophoretic display including the organic thin film transistor array panel shown in FIG. 1 and FIG. 2. Even though an electrophoretic display is shown in FIG. 18, the thin film transistor array panel according to an embodiment of the present invention may be applied to other flat panel displays such as a liquid crystal display, an organic light emitting device, etc.

The electrophoretic display includes the thin film transistor array panel shown in FIG. 1 and FIG. 2. Accordingly, descriptions of constituent elements of the organic thin film transistor array panel may be omitted. Many characteristics of the organic thin film transistor array panel shown in FIG. 1 and FIG. 2 can be applied to the electrophoretic display according to the present embodiment.

The electrophoretic display is formed by attaching an electrophoretic sheet of E-INK to the organic thin film transistor array panel of Exemplary Embodiment 1 of the present invention by a lamination method.

In detail, the electrophoretic sheet includes an insulation substrate 210, a common electrode 270 formed on one side of the substrate 210, a black matrix 220 disposed on the common electrode 270, a plurality of electrophoretic particles 230 disposed in pixel areas being divided by the black matrix 220, and an adhesive 240 disposed on the electrophoretic particles 230 to confine the electrophoretic particles 230 in the pixel areas.

Here, the adhesive 240 is used for attaching the electrophoretic sheet to the organic thin film transistor array panel. The common electrode 270 may be made of ITO or IZO.

In the organic thin film transistor array panel according to the embodiments of the present invention, the pixel electrodes 191 are formed on the passivation layer 180 such that the adhesive 240 is prevented from penetrating into the organic semiconductor islands 154 when the electrophoretic display is formed by attaching the electrophoretic sheet to the organic thin film transistor array panel by a lamination method. Accordingly, the deterioration of characteristics of the organic thin film transistor that occurs by the penetration of an adhesive material may be prevented.

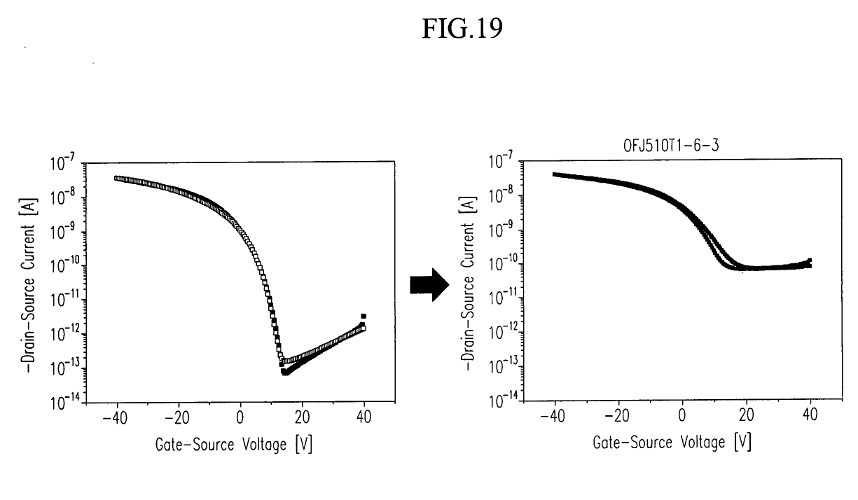

This will be described in detail with reference to graphs shown in FIG. 19 to FIG. 21.

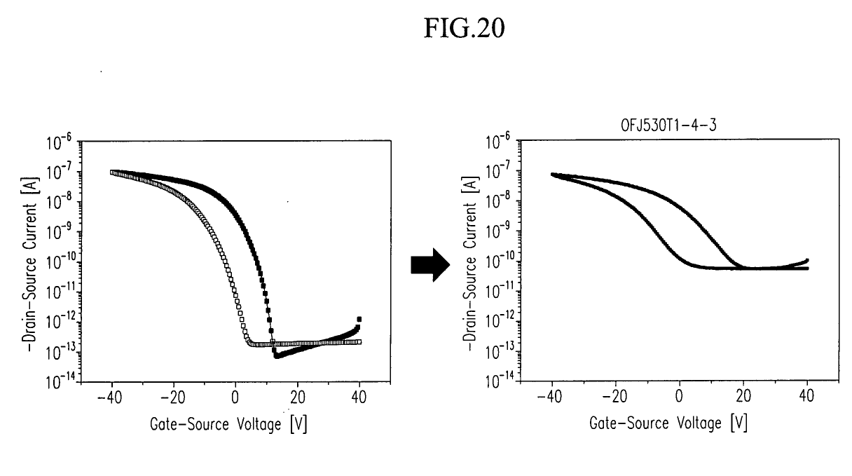

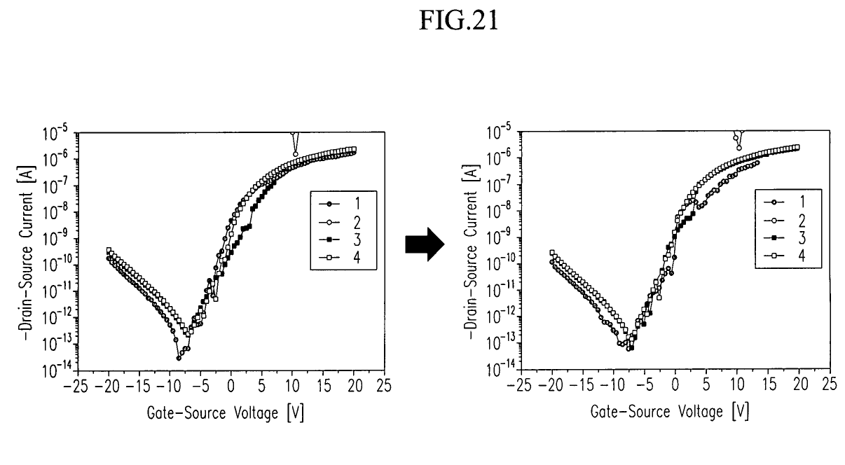

FIG. 19 and FIG. 20 are graphs representing characteristics of a thin film transistor in an organic thin film transistor array panel in which the organic thin film transistor is not covered by a pixel electrode, before/after an electrophoretic particles layer is attached to the thin film transistor array panel, and FIG. 21 is a graph representing characteristics of a thin film transistor in an organic thin film transistor array panel according to an embodiment of the present invention before/after an electrophoretic particles layer is attached to the thin film transistor array panel.

In FIG. 19, the gate insulation layer is made of an organic insulator, and in FIG. 20 the gate insulation layer is made of a silicon nitride layer. In FIG. 19 and FIG. 20, the graph at the left side represents current in an off state of the thin film transistor before the electrophoretic sheet is attached to the thin film transistor array panel, and the graph at the right side represents current in an off state of the thin film transistor after the electrophoretic sheet is attached to the thin film transistor array panel. Here, the organic thin film transistor is not covered by a pixel electrode. As shown in FIG. 19 and FIG. 20, the current in an off state is increased after the electrophoretic sheet is attached to the thin film transistor array panel.

In FIG. 21, the graph at the left side represents the current in an off state of the thin film transistor before the electrophoretic sheet is attached to the thin film transistor array panel, and the graph at the right side represents current in an off state of the thin film transistor after the electrophoretic sheet is attached to the thin film transistor array panel. Here, the organic thin film transistor is covered by a pixel electrode in the organic thin film transistor array panel according to an embodiment of the present invention. As shown in FIG. 21, the current in an off state may not vary after the electrophoretic sheet is attached to the thin film transistor array panel.

In the electrophoretic display, the electrophoretic particles 230 interposed between the pixel electrodes 191 and the common electrode 270 and having positive or negative charges are moved to the pixel electrode or the common electrode depending on the driving voltage such that external light incident on the electrophoretic display is absorbed or reflected by the electrophoretic particles that are moved and arranged in a different manner at each pixel area, and thereby the electrophoretic displays black, white, or various colors.

As described above, the organic thin film transistor array panel according to embodiments of the present invention includes a plurality of pixel electrodes 191 formed on the top layer such that the organic thin film transistor may be covered by the pixel electrodes 191 and display areas defined by the areas of the pixel electrodes 191 may be the largest. Accordingly, the aperture ratio of the display device including the organic thin film transistor array panel according to embodiments of the present invention may be increased to display images having a high luminance.

### Exemplary Embodiment 4

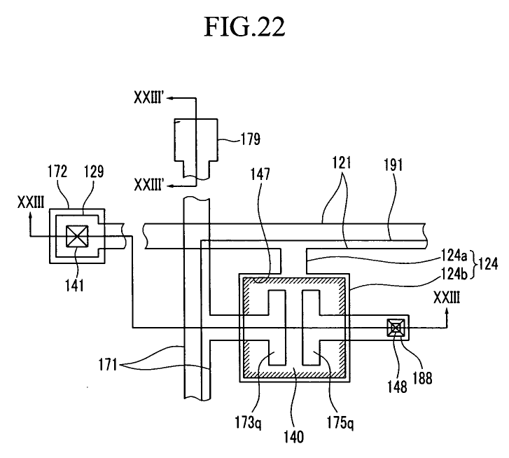

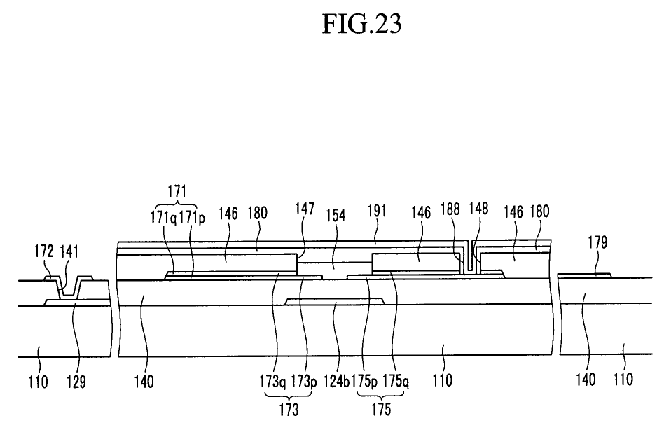

Now, a thin film transistor array panel according to another embodiment of the present invention will be described in detail with reference to FIG. 22 and FIG. 23.

FIG. 22 is a layout view of an organic thin film transistor array panel according to another embodiment of the present invention, and FIG. 23 is a sectional view of the organic thin film transistor array panel shown in FIG. 22 taken along the lines XXIII-XXIII and XXIII′-XXIII′.

A plurality of gate lines 121 are formed on an insulating substrate 110 made of a material such as transparent glass, silicone, or plastic.

The gate lines 121 transmit gate signals and extend substantially in a first direction (a transverse direction shown in FIG. 1). Each gate line 121 includes a plurality of gate electrodes 124 projecting in a second direction (a longitudinal direction shown in FIG. 1).

Each gate electrode 124 includes a connection portion 124a and an electrode portion 124b, and the electrode portion 124b is extended from the connection portion 124a in the first direction and the second direction to have a large area. However, the gate electrode 124 may have various shapes and arrangements. Each gate line 121 includes an end portion 129 having a large area for contact with another layer or an external driving circuit.

A gate driving circuit (not shown) for generating the gate signals may be mounted on an FPC film (not shown), which may be attached to the substrate 110, directly mounted on the substrate 110, or integrated with the substrate 110. The gate lines 121 may extend to be connected to a driving circuit that may be integrated with the substrate 110.

Meanwhile, the electrode portion 124b of the gate electrode 124 may have a large enough size enough to cover a pixel area such that a ratio of width to length (W/L) in a channel of an organic thin film transistor including the gate electrode 124 may be increased. Thereby, on current (Ion) of the thin film transistor may be increased such that the characteristics of the thin film transistors may be improved.

The gate lines 121 are preferably made of an Al-containing metal such as Al and an Al alloy, a Ag-containing metal such as Ag and a Ag alloy, a Cu-containing metal such as Cu and a Cu alloy, a Mo-containing metal such as Mo and a Mo alloy, Cr, Ta, Ti, and W.

However, they may have a multi-layered structure including two conductive films (not shown) having different physical characteristics. For example, the gate lines 121 and the storage electrode lines 131 may have a double-layered structure including a conductive oxide layer such as ITO (indium tin oxide) and IZO (indium zinc oxide), and a low resistivity metal conductive layer.

A gate insulating layer 140 having a plurality of holes 141 exposing the end portions 129 of the gate lines 121 is formed on the substrate 110, the gate lines 121, and the substrate 110.

The gate insulation layer 140 may be made of an inorganic insulator or an organic insulator. Examples of the inorganic insulator include silicon nitride and silicon oxide that may have their surface treated with octadecyl-trichloro-silane (OTS), and examples of the organic insulator include hydrocarbon-based polymers including fluorine and parylene that can be deposited by chemical vapor deposition (CVD) under vacuum.

A plurality of data lines 171 including a plurality of source electrodes 173 and an end portion 179 having a large area for contact with another layer or an external driving circuit, a plurality of drain electrodes 175, and a plurality of contact assistants 172 are formed on the gate insulation layer 140.

The data lines 171 transmit data signals and extend substantially in a longitudinal direction to intersect the gate lines 121.

Each of the source electrodes 173 includes a linear portion and an extension portion extending upward and downward from an end of the linear portion.

A data driving circuit (not shown) for generating the data signals may be mounted on a flexible printed circuit (FPC) film (not shown), which may be attached to the substrate 110, directly mounted on the substrate 110, or integrated with the substrate 110. The data lines 121 may extend to be connected to a driving circuit that may be integrated with the substrate 110.

Each of the drain electrodes 175 is an island type, and includes a linear portion and an extension portion extending upward and downward from an end of the linear portion. The extension portion of the drain electrode 175 is parallel to the extension portion of the source electrode 173 and is opposite to the extension portion of the source electrode 173.

The extension portion of the source electrode 173 and the extension portion of the drain electrode 175 may be preferably elongated within the condition that the lengths of the extension portions are not longer than the length of each gate electrode 124 in the second direction.

Accordingly, a ratio of width to length (W/L) in a channel of a thin film transistor including the source electrode 173 and the drain electrode 175 may be increased, and thereby the characteristics of the thin film transistors may be improved.

The data lines 171 may have a multi-layered structure including two conductive layers 171p and 171q having different physical properties from each other.

The lower layer 171p may be preferably made of a transparent conductive oxide such as ITO (indium tin oxide) and IZO (indium zinc oxide).

The upper layer 171q may be preferably made of a low resistivity metal such as an Al-containing metal, a Ag-containing metal, a Au-containing metal, a Cu-containing metal, a Mo-containing metal, Cr, Ta, and Ti.

Here, the upper layer 171q is removed in the end portions 179 of the data lines 171 to expose the lower layer 171p. Accordingly, the end portions 179 of the data lines 171 may be made of a transparent conductive oxide such as ITO (indium tin oxide) and IZO (indium zinc oxide).

The source electrodes 173 include the lower layer 173p and the upper layer 173q except at portions where the source electrodes 173 contact the organic semiconductor islands 154, and the source electrodes 173 include only the lower layer 173p at those portions.

Similarly, the drain electrodes 175 include the lower layer 175p and the upper layer 175q except at portions where the drain electrodes 175 contact the organic semiconductor islands 154, and the drain electrodes 175 include only the lower layer 175p at those portions.

The contact assistants 172 are composed of the lower layer.

As described above, the lower layers 171p, 173p, and 175p of the data lines 171, the source electrodes 173, and the drain electrodes 175 are made of the same material, for example a transparent conductive oxide, and the end portions 179 of the data lines 171 and the contact assistants 172 are made of the same transparent conductive oxide as the layers 171p, 173p, and 175p.

If the upper layers 173q and 175q of the source electrodes 173 and the drain electrodes 175 are made of a material having a good contact characteristic to the semiconductor, the upper layers 173q and 175q of the source electrodes 173 and the drain electrodes 175 may not be removed at the portions where the drain electrodes 175 contact the semiconductor islands 154.

A bank 146 is formed on the substrate 110 having the data lines 171 and the drain electrodes 175.

The bank 146 has a plurality of first holes 147 having a slightly smaller size than that of the electrode portions 124b of the gate electrodes 124 and that expose the portions of the source electrodes 173 and the drain electrodes 175, and a plurality of second holes 148 exposing the end portions of the linear portions of the drain electrodes 175. The source electrodes 173 and the drain electrodes 175 are opposite to each other in the first holes 147.

The source electrodes 173 and the drain electrodes 175 that are exposed through the first holes 147 of the bank 146 are composed of the lower layers 173p and 175p.

Even though the first hole 147 has a quadrangle planar shape in FIG. 22, the first holes 147 may have an oval planar shape or a circular planar shape.

A plurality of semiconductor islands 154 are formed on the source electrodes 173, the drain electrode 175, and the gate insulating layer 140 in the first holes 147, respectively. The semiconductor islands 154 may be made of an organic semiconductor, nanoparticles, or an inorganic semiconductor.

The inorganic semiconductor includes Si, and the organic semiconductor may be an oligomer or polymer having a structure in which electrons may easily move, such as a conjugated system.

The organic semiconductor islands 154 may include a high molecular compound or a low molecular compound that is soluble in an aqueous solution or an organic solvent. The organic semiconductor islands 154 may be made of polythienylenevinylene, poly 3-hexylthiophene, polythiophene, phthalocyanine, metallized phthalocyanine, or their halogenated derivatives; of perylenetetracarboxylic dianhydride (PTCDA), naphthalenetetracarboxylic dianhydride (NTCDA), or their imide derivatives; or of perylene, coronene, or derivatives thereof with a substituent.

The semiconductor islands 154 may have the same planar size as that of the first holes 147. The semiconductor islands 154 are disposed on the gate electrodes 124, and contact the source electrodes 173 and the drain electrodes 175 in the first holes 147.

Here, the first holes 147 have a slightly smaller size than the electrode portions 124b of the gate electrodes 124 as described above. Accordingly, the semiconductor islands 154 have a slightly smaller size than the electrode portions 124b of the gate electrodes 124 such that the semiconductor islands 154 are not directly exposed to external light incident on the gate electrodes 124, and thereby light leakage (photo leakage) occurring by the light incident on the semiconductor islands 154 may be prevented.

A gate electrode 124, a source electrode 173, and a drain electrode 175 along with a semiconductor island 154 form a thin film transistor having a channel formed in the semiconductor island 154 disposed between the source electrode 173 and the drain electrode 175.

The semiconductor islands 154 may be imprinted in the first holes 147 by an inkjet printing method using an ink including the semiconductor material. Here, it is important that the ink including the semiconductor material is selectively put in the holes 147 by inkjet printing.

In the present embodiment, the bank 146 is subjected to plasma treatment including fluorine such that the inside of the bank 146 may include fluorine. The fluorine increases the contact angle of the ink including the semiconductor material to the bank 146, when the semiconductor islands 154 are formed by an inkjet printing method. Accordingly, the surface of the bank 146 does not easily get wet with the ink including the semiconductor material such that the ink including the semiconductor material is induced to flow into the first holes 147 of the bank 146. Thereby, the semiconductor islands 154 may be effectively formed in the first holes 147 of the bank 146.

Here, portions of the gate insulation layer 140 disposed in the first holes 147 may included fluorine. In FIG. 22, the region including fluorine is denoted using a slanting crease line, and the region including fluorine is formed to have a ring planar shape along with the inner edge of the first holes 147.

Accordingly, a ratio of width to length (W/L) in a channel of the thin film transistors including the semiconductor islands 54 formed in the first hole 147 may be increased, and the semiconductor islands 154 may be effectively formed in the first holes 147 of the bank 146 by an inkjet printing method.

A passivation layer 180 is formed on the bank 146 and the organic semiconductors 154. The passivation layer 180 has a plurality of contact holes 188 communicating with the second holes 148 of the bank 146. In the present embodiment, the passivation layer 180 covers the semiconductor islands 154 such that the semiconductor islands 154 may be prevented from being damaged in method processes.

A plurality of pixel electrodes 191 are formed on the passivation layer 180. The pixel electrodes 191 are connected to the drain electrodes 175 through the contact holes 148 and 188, and receive data voltages from the drain electrodes 175 of the thin film transistors. The pixel electrodes 191 may be made of an opaque metal material. However, the pixel electrodes 191 may be made of a transparent conductive oxide layer such as ITO (indium tin oxide) and IZO (indium zinc oxide).

The pixel electrodes 191 supplied with the data voltages generate electric fields in cooperation with a common electrode (not shown) of an opposing display panel (not shown) supplied with a common voltage, which drive an electro-optical active layer such as electrophoretic particle layer (not shown) interposed therebetween.

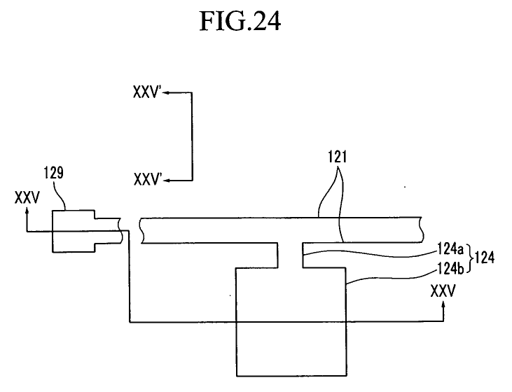

Now, a manufacturing method of the thin film transistor array panel shown in FIG. 22 and FIG. 23 will be described in detail with reference to FIG. 24 to FIG. 35.

FIG. 24, FIG. 26, FIG. 28, FIG. 30, and FIG. 32 are layout views of the organic thin film transistor array panel shown in FIG. 22 and FIG. 23 in intermediate steps of a manufacturing method thereof according to another embodiment of the present invention

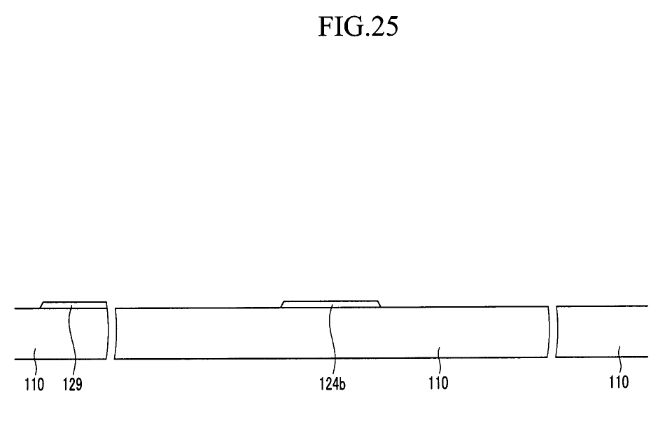

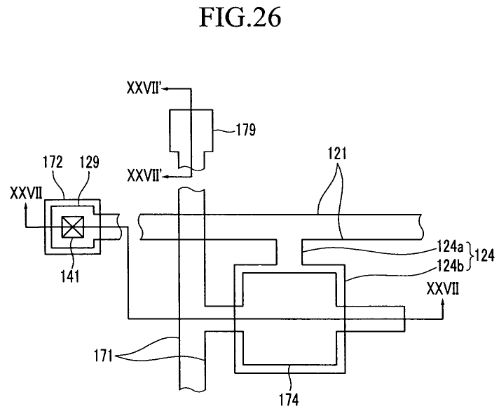

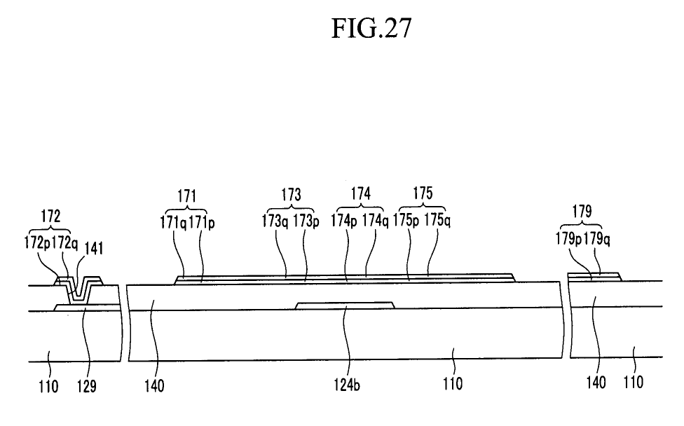

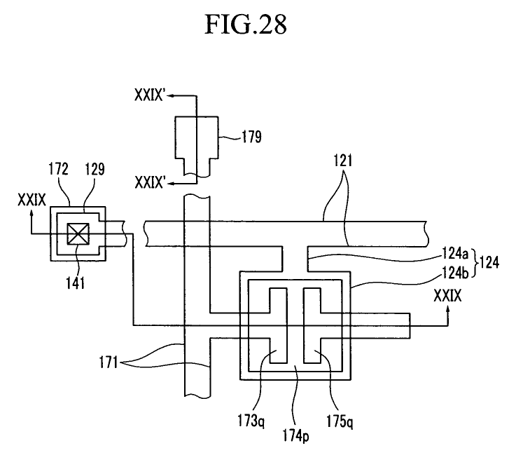

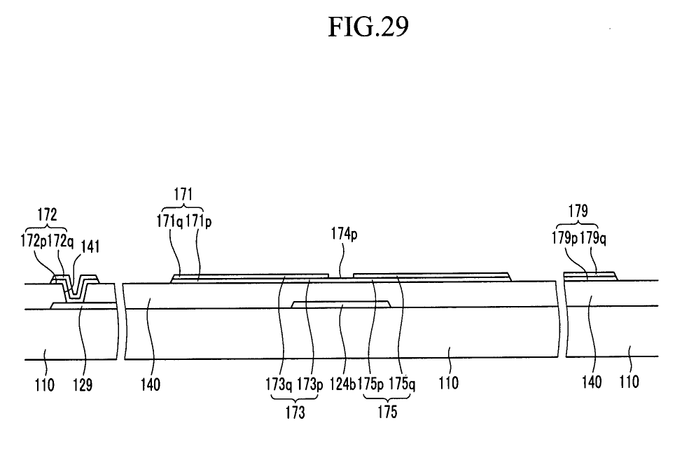

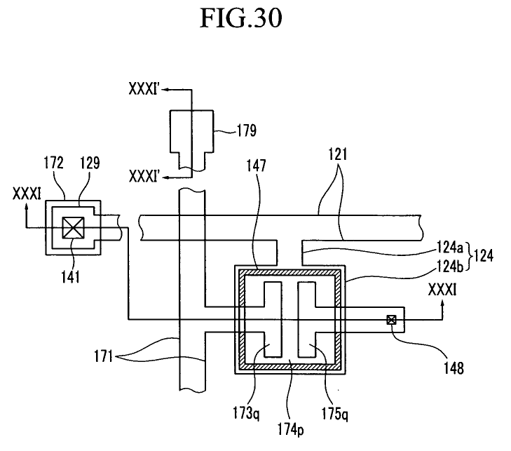

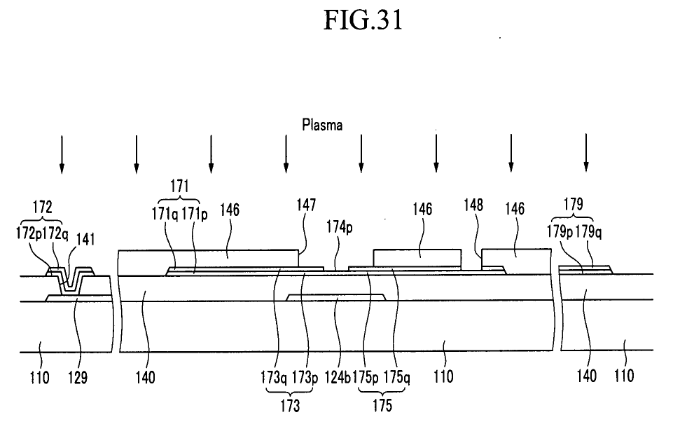

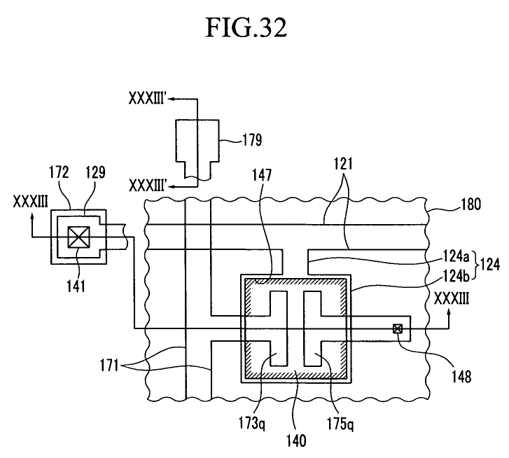

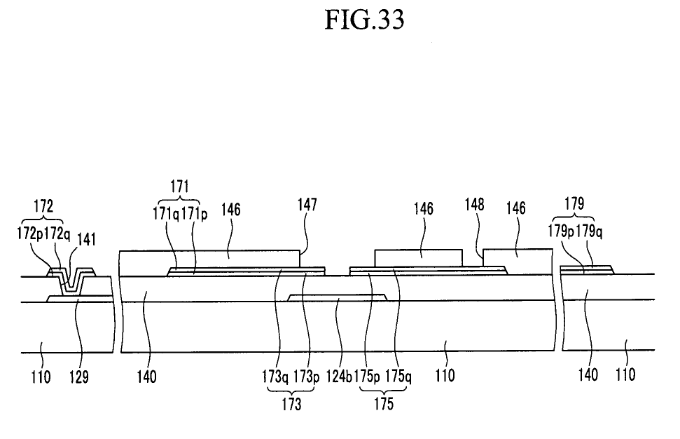

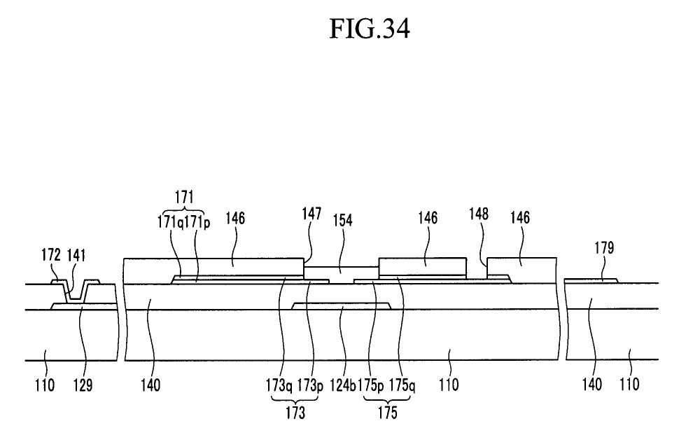

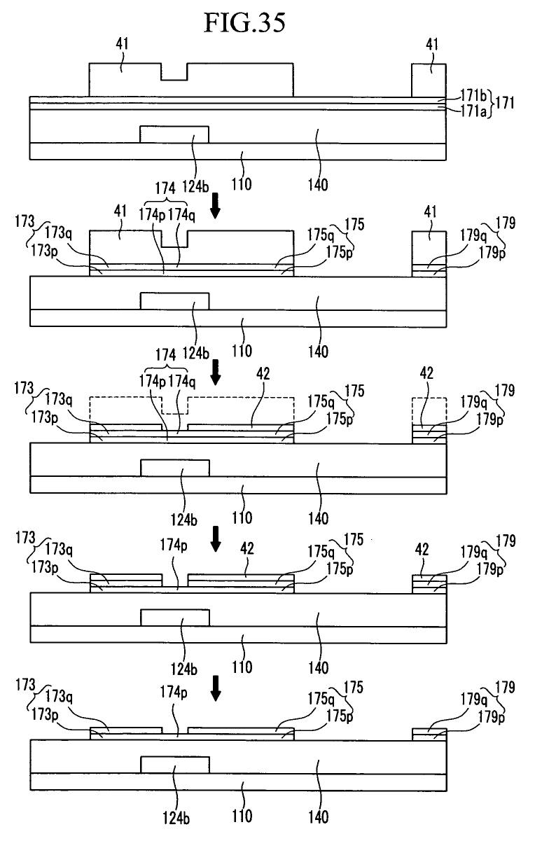

FIG. 25 is a sectional view of the organic thin film transistor array panel shown in FIG. 24 taken along the lines XXV-XXV and XXV′-XXV′, FIG. 27 is a sectional view of the organic thin film transistor array panel shown in FIG. 26 taken along the lines XXVII-XXVII and XXVII′-XXVII′, FIG. 29 is a sectional view of the organic thin film transistor array panel shown in FIG. 28 taken along the lines XXIX-XXIX and XXIX′-XXIX′, FIG. 31 is a sectional view of the organic thin film transistor array panel shown in FIG. 30 taken along the lines XXXI-XXXI and XXXI′-XXXI′, and FIG. 33 is a sectional view of the organic thin film transistor array panel shown in FIG. 32 taken along the lines XXXIII-XXXIII and XXXIII′-XXXIII′. FIG. 34 is a sectional view of the organic thin film transistor array panel shown in FIG. 33 after the next processes, and FIG. 35 is a sectional view of the organic thin film transistor array panel shown in FIG. 26 to FIG. 29 for representing the manufacturing method.

First, a gate metal layer such as aluminum and molybdenum is deposited on a substrate 110 and patterned by photolithography and etching to form a plurality of gate lines 121 including a plurality of gate electrodes 124 and end portions 129, as shown in FIG. 24 and FIG. 25.

Referring to FIG. 26, FIG. 27, and FIG. 35, an insulating layer is deposited on the substrate 110 and the gate lines 121, and the insulating layer is patterned by photolithography and etching to form a gate insulation layer 140 having a plurality of contact holes 141 exposing the end portions 129 of the gate lines 121.

Next, a lower conducting layer made of a transparent conductive material such as ITO and an upper conducting layer made of a metal such as molybdenum are sequentially deposited on the substrate 110 and the gate insulating layer 140, and patterned by photolithography and etching to form a data pattern including a lower layer 171p, 172p, 173p, 174p, 175p, and 179p and an upper layer 171q, 172q, 173q, 174q, 175q, and 179q. The data pattern includes a plurality of data lines 171 including a plurality of source electrodes 173 and a plurality of end portions 179, a plurality of drain electrodes 175, a plurality of contact assistants 172, and a plurality of connection portions between the source electrodes 173 and the drain electrodes 175, as shown in FIG. 26 and FIG. 27. H ere, referring to FIG. 35, a photosensitive layer is coated on the upper conducting layer, the coated photosensitive layer is exposed using a halftone mask, and then the exposed coated photosensitive layer is developed to form the first photosensitive layer patterns 41. Next, the upper conducting layer and the lower conducting layer are etched by using the first photosensitive layer patterns 41 as an etching mask to form the data pattern including the lower layers 171p, 172p, 173p, 174p, 175p, and 179p and the upper layers 171q, 172q, 173q, 174q, 175q, and 179q.

Next, referring to FIG. 28, FIG. 29, and FIG. 35, the first photosensitive layer patterns 41 are etched back to form second photosensitive layer patterns 42. Then, the upper layers 174q of the connection portions 174 between the source electrodes 173 and the drain electrodes 175 disposed over the gate electrodes 124 are etched by using the second photosensitive layer patterns 42 as an etching mask to form a plurality of block portions 174p, and then the second photosensitive layer patterns 42 are removed.

Next, an organic insulator is coated and patterned by photolithography and etching to form a bank 146 having a plurality of first holes 147 and a plurality of second holes 148 exposing portions of the electrodes 173 and the drain electrodes 175 disposed over the gate electrodes 124 and exposing the end portions of the drain electrodes 175, as shown in FIG. 30 and FIG. 31. Here, the first holes 147 have a slightly smaller size than that of the electrode portions 124b of the gate electrodes 124, and have a larger size than that of the block portions 174p to expose portions of the source electrodes 173 and the drain electrodes 175.

Here, when the organic insulator has photosensitivity, the bank 146 may be formed by photolithography.

Next, the entire surface of the substrate 110 is subjected to CF₄ plasma treatment. Through the fluorine plasma treatment, the bank 146 that is made of an organic insulator absorbs fluorine at its inside. Here, the distribution of fluorine inside the bank 146 may be varied with the duration time of the plasma treatment.

For example, the fluorine may be distributed uniformly over the entire inside of the bank 146, and the concentration of fluorine may be high at the upper side of the bank 146 and low at the lower side of the bank 146.

During the plasma treatment, the gate insulation layer 140 disposed in the first holes 147 may be protected by the block portions 174p.

Accordingly, the gate insulation layer 140 includes fluorine at portions not covered with the block portions 174p and the data conductive layers such as portions denoted using a slanting crease line in FIG. 30, and the portions have a ring planar shape along with the inner edge of the first holes 147. Thereby, even though the gate insulation layer 140 is made of an organic insulator, the gate insulation layer 140 may be prevented from being damaged during the plasma treatment such that deterioration of characteristics of the thin film transistor that may occur because of damage to the gate insulation layer 140 may thus be prevented.

Next, referring to FIG. 32 and FIG. 33, the block portions 174p are etched by using the upper layers 173q and 175q disposed in the first holes 147 as an etching mask to eliminate the block portions 174p.

As described above, the first holes 147 have a larger size than that of the block portions 174p over the electrode portions 124b of the gate electrodes 124 such that the block portions 174p may be completely removed to prevent a short circuit between the source electrodes 173 and the drain electrodes 175 due to the block portions 174p.

Referring to FIG. 34, the upper layers 172q, 173q, 175q, and 179q of the source electrodes 173 and the drain electrodes 175 disposed in the first holes 147 of the bank 146, the end portions 179 of the data lines 171, and the contact assistants 172 are etched to be eliminated by using the bank 146 as an etching mask.

Next, an ink including semiconductor materials is dripped in the first holes 147 of the bank 146 by an inkjet printing method and dried to form a plurality of semiconductor islands 154. Here, the bank 146 contains fluorine because of the plasma treatment, and the gate insulation layer 140 in the first holes 147 does not contain fluorine.

The fluorine causes the contact angle of the ink including semiconductor materials to be increased. Accordingly, the ink dripped on the bank 146 may be induced to flow to the inside of the first holes 147 having a smaller contact angle, i.e., being easily wetted with the ink, than the surface of the bank 146, and thereby the semiconductor islands 154 may be effectively formed in the first holes 147 to contact the source electrodes 173 and the drain electrodes 175.

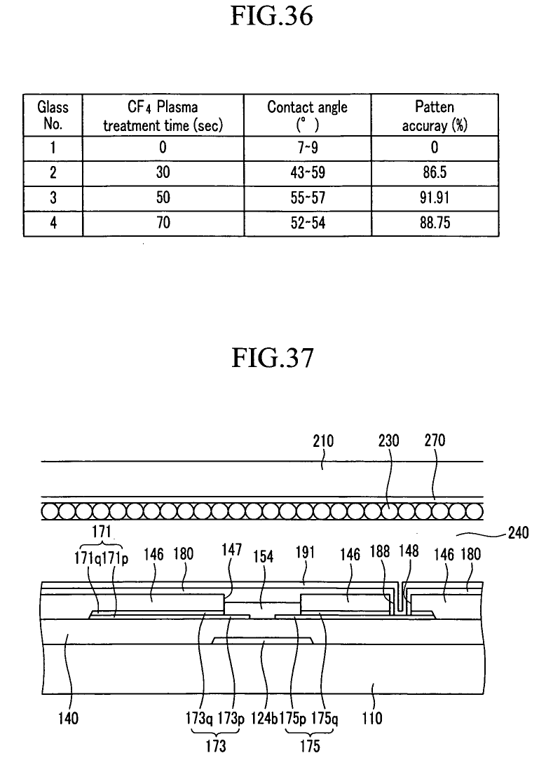

FIG. 36 is a table representing contact angle and pattern accuracy according to a fluorine plasma treatment. Referring to the table, the contact angle is low and the pattern accuracy of the semiconductor is about 0% without the fluorine plasma treatment. The fluorine plasma treatment causes the ink contact angle to be increased and the pattern accuracy of the semiconductor to be improved.

Meanwhile, the second holes 148 may be formed far from the first holes 147 for preventing the ink dripped on the bank 146 from filling the second holes 148 within the range of possibility.

The disposition of the second holes 148 may be varied along with variation of the shape of the drain electrodes 175.

Next, a passivation layer 180 having a plurality of contact holes communicating with the second holes 148 of the bank 146 is formed, as shown in FIG. 22 and FIG. 23.

Finally, an opaque metal layer such as chromium is deposited on the passivation layer 180 and patterned by photolithography and etching to form a plurality of pixel electrodes 191 connected to the drain electrodes 175 through the contact holes 148 and 188 as shown in FIG. 22 and FIG. 23.

### Exemplary Embodiment 5

Now, a flat panel display including a thin film transistor array panel according to another embodiment of the present invention will be described in detail with reference to FIG. 37. FIG. 37 is a sectional view of an electrophoretic display including the organic thin film transistor array panel shown in FIG. 22 and FIG. 23. Even though an electrophoretic display is shown in FIG. 37, the thin film transistor array panel according to an embodiment of the present invention may be applied to other flat panel displays such as a liquid crystal display, an organic light emitting device, etc.

The electrophoretic display includes the thin film transistor array panel shown in FIG. 22 and FIG. 23. Accordingly, description of constituent elements of the organic thin film transistor array panel may be omitted. Many characteristics of the organic thin film transistor array panel shown in FIG. 22 and FIG. 23 can be applied to the electrophoretic display according to the present embodiment.

The electrophoretic display is formed by attaching an electrophoretic sheet of E-INK to the organic thin film transistor array panel of Exemplary Embodiment 4 of the present invention by a lamination method.

In detail, the electrophoretic sheet includes an insulation substrate 210, a common electrode 270 formed on one side of the substrate 210, a black matrix 220 disposed on the common electrode 270, a plurality of electrophoretic particles 230 disposed in pixel areas being divided by the black matrix 220, and an adhesive 240 disposed on the electrophoretic particles 230 to confine the electrophoretic particles 230 in the pixel areas.

Here, the adhesive 240 is used for attaching the electrophoretic sheet to the organic thin film transistor array panel. The common electrode 270 may be made of ITO or IZO.

In the organic thin film transistor array panel according to the embodiments of the present invention, the pixel electrodes 191 are formed on the passivation layer 180 such that the adhesive 240 is prevented from penetrating into the organic semiconductor islands 154 when the electrophoretic display is formed by attaching the electrophoretic sheet to the organic thin film transistor array panel by a lamination method. Accordingly, the deterioration of characteristics of the organic thin film transistor that may occur because of the penetration of an adhesive material may be prevented.

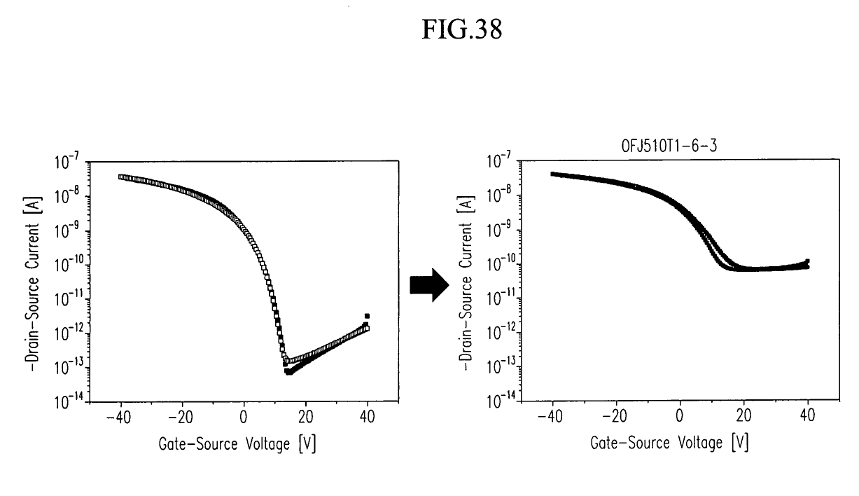

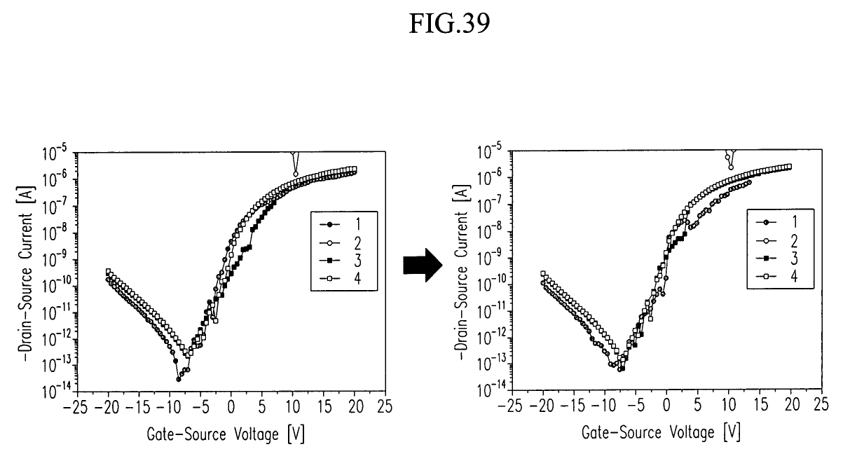

This will be described in detail with reference to graphs shown in FIG. 38 and FIG. 39.

FIG. 38 shows graphs representing characteristics of a thin film transistor in an organic thin film transistor array panel in which the organic thin film transistor is not covered by a pixel electrode, before/after an electrophoretic particle layer is attached to a thin film transistor array panel, and FIG. 39 shows graphs representing characteristics of a thin film transistor in an organic thin film transistor array panel according to an embodiment of the present invention before/after an electrophoretic particle layer is attached to a thin film transistor array panel.

In FIG. 38, the graph at the left side represents current in an off state of the thin film transistor before the electrophoretic sheet is attached to the thin film transistor array panel, and the graph at the right side represents current in an off state of the thin film transistor after the electrophoretic sheet is attached to the thin film transistor array panel. Here, the organic thin film transistor is not covered by a pixel electrode.

As shown in FIG. 38, the current in the off state is increased after the electrophoretic sheet is attached to the thin film transistor array panel.

In FIG. 39, the graph at the left side represents current in an off state of the thin film transistor before the electrophoretic sheet is attached to the thin film transistor array panel, and the graph at the right side represents current in an off state of the thin film transistor after the electrophoretic sheet is attached to the thin film transistor array panel. Here, the organic thin film transistor is covered by a pixel electrode in the organic thin film transistor array panel according to an embodiment of the present invention. As shown in FIG. 39, the current in an off state may not be varied after the electrophoretic sheet is attached to the thin film transistor array panel.

In the electrophoretic display, the electrophoretic particles 230 interposed between the pixel electrodes 191 and the common electrode 270 and having positive or negative charges are moved to the pixel electrode or the common electrode depending on the driving voltage such that external light incident on the electrophoretic display is absorbed or reflected by the electrophoretic particles that are moved and arranged in a different manner at each pixel area, and thereby the electrophoretic displays black, white, or various colors.

As described above, the organic thin film transistor array panel according to embodiments of the present invention includes a plurality of pixel electrodes 191 formed on the top layer such that the organic thin film transistor may be covered by the pixel electrodes 191 and display areas defined by the areas of the pixel electrodes 191 may be the largest. Accordingly, the aperture ratio of the display device including the organic thin film transistor array panel according to embodiments of the present invention may be increased to display images having a high luminance.

In addition, a ratio of width to length (W/L) in a channel of an organic thin film transistor may be increased, and thereby an on current (Ion) of the organic thin film transistor may be increased such that the characteristics of the organic thin film transistors may be improved. The organic semiconductor may be prevented from overflowing from the holes while forming the organic semiconductor in the holes by an inkjet printing method such that characteristics deterioration of the thin film transistor and pixel defect may be prevented.

The adhesive of the electrophoretic sheet is prevented from penetrating into the organic semiconductor when the electrophoretic display is formed by attaching the electrophoretic sheet to the organic thin film transistor array panel by a lamination method. Accordingly, the deterioration of characteristics of the organic thin film transistor that occur because of the penetration of an adhesive material may be prevented.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel, comprising:
a substrate;
a gate line formed on the substrate, extending in a first direction, and including a gate electrode;
a storage electrode line formed on the substrate;
a gate insulation layer covering the gate line and the storage electrode line;
a data line formed on the gate insulation layer, extending in a second direction to cross the gate line, and including a source electrode;
a drain electrode separated from the data line and facing the source electrode;
a bank having a first hole exposing the source electrode and the drain electrode;
an organic semiconductor formed in the first hole and connected to the source electrode and the drain electrode;
a passivation layer covering the bank and the organic semiconductor; and
a pixel electrode formed on the passivation layer and connected to the drain electrode.

2. The thin film transistor array panel of claim 1, wherein the pixel electrode partially overlaps the organic semiconductor, the bank, the source electrode, and the drain electrode.

3. The thin film transistor array panel of claim 2, wherein the gate electrode extends in a second direction, and the length L1 of the gate electrode satisfies the relationship to the interval G1 between the gate line and the storage electrode line 131 as follows: 0.2G1<L1<G1.

4. The thin film transistor array panel of claim 3, wherein the planar shape of the first hole of the bank is one of a rectangle shape, a square shape, an oval shape, and a circular shape.

5. The thin film transistor array panel of claim 3, wherein the size (the length in first direction×the length in the second direction) of the first hole of the bank is one of about 50 μm×50 μm, about 60 μm×80 μm, about 80 μm×80 μm, and about 100 μm×200 μm.

6. The thin film transistor array panel of one of claim 1 to claim 5, wherein the source electrode includes a linear portion and an extension portion extending in the second direction from an end of the linear portion, and the drain electrode includes a first linear portion extending in the first direction, a second linear portion extending in the second direction from the end of the first linear portion, a third linear portion extending toward the source electrode in the first direction from a middle portion of the second linear portion, and an extension portion extending in the second direction from the end of the third linear portion to be opposite to the source electrode.

7. The thin film transistor array panel of claim 6, wherein the storage electrode line extends in the first direction and includes a storage electrode extending in the second direction, and the first linear portion of the drain electrode overlaps the storage electrode line and the second linear portion of the drain electrode overlaps the storage electrode.

8. The thin film transistor array panel of claim 6, wherein the pixel electrode is connected to the drain electrode through a second hole of the bank, and the second hole exposes an end portion of the third linear portion of the drain electrode.

9. The thin film transistor array panel of claim 8, wherein a distance between the first hole and the second hole is about 70 μm or more.

10. The thin film transistor array panel of claim 9, wherein a distance between two adjacent first holes of the bank is about 100 μm or more.

11. The thin film transistor array panel of claim 6, wherein the data line includes a first layer made of a transparent conductive oxide and a second layer made of a low resistivity metal, and the source electrode and the drain electrode include a first layer made of a transparent conductive oxide.

12. The thin film transistor array panel of claim 6, wherein the data line includes a first layer made of a transparent conductive oxide and a second layer made of a low resistivity metal, and portions of the source electrode and the drain electrode contacting the organic semiconductor include a first layer made of a transparent conductive oxide.

13. The thin film transistor array panel of claim 6, wherein the passivation layer has a double-layered structure including a lower passivation layer made of a non-photosensitive insulating material and an upper passivation layer made of a photosensitive insulating material and disposed on the lower passivation layer.

14. A flat panel display, comprising:
an organic thin film transistor array panel;
a common electrode panel facing the organic thin film transistor array panel; and
electrophoretic particles disposed between the organic thin film transistor array panel and the common electrode panel,
wherein the organic thin film transistor array panel comprises
a substrate,
a gate line formed on the substrate, extending in a first direction, and including a gate electrode,
a storage electrode line formed on the substrate,
a gate insulation layer covering the gate line and the storage electrode line,
a data line formed on the gate insulation layer, extending in a second direction to cross the gate line, and including a source electrode,
a drain electrode facing the source electrode,
a bank including a first hole exposing the source electrode and the drain electrode,
an organic semiconductor formed in the first hole and connected to the source electrode and the drain electrode,
a passivation layer covering the bank and the organic semiconductor, and
a pixel electrode formed on the protective layer and connected to the drain electrode.

15. The flat panel display of claim 14, wherein the size (the length in first direction×the length in the second direction) of the first hole of the bank is one of about 50 μm×50 μm, about 60 μm×80 μm, about 80 μm×80 μ, and about 100 μm×200 μm.

16. A manufacturing method for a thin film transistor array panel, comprising:
forming a gate line and a storage electrode line parallel to the gate line on a substrate;
forming a gate insulation layer on the gate line, the storage electrode line, and the substrate;
forming a data line, a source electrode, and a drain electrode on the gate insulation layer;
forming a bank having a first hole and a second hole on the gate insulation layer, the data line, the source electrode, and the drain electrode;
forming an organic semiconductor in the first hole of the bank;
forming a passivation layer having a hole aligned with the second hole of the bank on the bank and the organic semiconductor; and
forming a pixel electrode on the passivation layer.

17. The manufacturing method of claim 16, wherein the forming of the organic semiconductor is performed by inkjet printing.

18. The manufacturing method of claim 16, wherein the forming of the passivation layer comprises:
depositing a non-photosensitive insulating layer;
depositing a photosensitive insulating layer on the non-photosensitive insulation layer;
patterning the photosensitive insulating layer by photolithography; and
etching the non-photosensitive insulating layer by using the patterned photosensitive insulation layer as an etching mask.

19. The manufacturing method of claim 16, wherein the forming of the data line, the source electrode, and the drain electrode comprises:
sequentially depositing a lower conducting layer such as ITO and an upper conducting layer such as molybdenum;
coating a photosensitive layer on the upper metal layer and exposing and developing the coated photosensitive layer to form a first photosensitive layer pattern;
etching the upper conducting layer and the lower conducting layer by using the first photosensitive layer pattern as an etching mask to remove the upper conducting layer and the lower conducting layer except the data line, the source electrode, and the drain electrode;
ashing the first photosensitive layer pattern to form a second photosensitive layer pattern; and
etching the upper conducting layer by using the second photosensitive layer pattern as an etching mask to remove the upper conducting layer of portions of the source electrode and the drain electrode.

20. The manufacturing method of claim 16, wherein the forming of the data line, the source electrode, and the drain electrode comprises:
sequentially depositing a lower conducting layer such as ITO and an upper conducting layer such as molybdenum;
patterning the upper conducting layer and the lower conducting layer to the data line, the source electrode, and the drain electrode including the upper conducting layer and the lower conducting layer;
forming a bank having a first hole and a second hole on the gate insulation layer, the data line, the source electrode, and the drain electrode; and
etching the upper conducting layer by using the bank as an etching mask to remove the upper conducting layer of the source electrode and the drain electrode disposed in the first hole and expose the lower conducting layer of the source electrode and the drain electrode disposed in the first hole.

21. The manufacturing method of claim 16, wherein a contact hole exposing an end portion of the gate line is formed in the gate insulation layer during the forming of the gate insulation layer, and contact assistants contacting end portion of the gate line through the contact hole are formed during the forming of the data line, the source electrode, and the drain electrode.

22. A thin film transistor array panel, comprising:
a substrate;
a gate line formed on the substrate, extending in a first direction, and including a gate electrode;
a gate insulation layer formed on the gate line and containing fluorine in a portion thereof;
a data line formed on the gate insulation layer, extending in a second direction to cross the gate line, and including a source electrode;
a drain electrode separated from the data line and facing the source electrode;
a bank including a first hole exposing the source electrode and the drain electrode and disposed on the source electrode and the drain electrode;
a semiconductor formed in the first hole and connected to the source electrode and the drain electrode to form a channel of a thin film transistor;
a passivation layer covering the bank and the semiconductor; and
a pixel electrode formed on the passivation layer and connected to the drain electrode.

23. The thin film transistor array panel of claim 22, wherein the portion of the gate insulation layer containing the fluorine has a ring planar shape formed along with the inner edge of the first hole.

24. The thin film transistor array panel of claim 22, wherein the bank contains the fluorine by being subjected to a plasma treatment

25. The thin film transistor array panel of claim 22, wherein the gate insulation layer includes an organic insulator.

26. The thin film transistor array panel of claim 22, wherein the data line includes a lower layer including a transparent conductive oxide and an upper layer including a metal, portions of the source electrode and drain electrode disposed in the first hole are composed of the lower layer, and remaining portions of the source electrode and drain electrode are composed of the upper layer.

27. The thin film transistor array panel of claim 26, further comprising contact assistants formed on the gate insulation layer, contacting an end portion of the gate line through a contact hole, and composed of the lower layer, and wherein the data line includes an end portion having a large area and composed of the lower layer, and the portion of the gate insulation layer containing the fluorine further includes a peripheral area of the end portion of the data line.

28. The thin film transistor array panel of claim 27, wherein the first hole has a smaller area than that of the gate electrode and is disposed over the gate electrode.

29. The thin film transistor array panel of claim 28, wherein the pixel electrode covers the semiconductor.

30. The thin film transistor array panel of claim 22, further comprising contact assistants formed on the gate insulation layer, contacting an end portion of the gate line through a contact hole, and composed of the lower layer, and wherein the data line includes an end portion having a large area and composed of the lower layer, and the portion of the gate insulation layer containing the fluorine further includes a peripheral area of the end portion of the data line.

31. A manufacturing method for a thin film transistor array panel, comprising:
A) forming a gate line including a gate electrode on a substrate;
B) forming a gate insulation layer on the gate line and the substrate;
C) sequentially depositing a first conductive layer and a second conductive layer on the gate insulation layer;
D) patterning the first conductive layer and the second conductive layer to form a data line, a source electrode, and a drain electrode composed of the first conductive layer and the second conductive layer, and a block portion disposed over the gate electrode, connected to the source electrode and the drain electrode, and composed of the first conductive layer;
E) forming a bank having a first hole exposing the source electrode, the drain electrode, and the block portion;
F) performing fluorine plasma treatment on the bank;
G) etching the first conductive layer by using the second conductive layer exposed through the first hole as an etching mask to remove the block portion;
H) forming a semiconductor in the first hole;
I) forming a passivation layer on the bank and the semiconductor; and
I) forming a pixel electrode on the passivation layer.

31. The manufacturing method of claim 30, wherein the forming of the semiconductor is performed by dripping a semiconductor material into the first hole by inkjet printing.

32. The manufacturing method of claim 30, wherein the step of D) comprises:
D-1) coating a photosensitive layer on the second conductive layer and exposing and developing the coated photosensitive layer by using a halftone mask to form a first photosensitive layer pattern;
D-2) etching the first conductive layer and the second conductive layer by using the first photosensitive layer pattern as an etching mask to form a data pattern composed of the first conductive layer and the second conductive layer and including the data line, the source electrode, the drain electrode, and a connection portion between the source electrode and the drain electrode;
D-3) etching back the first photosensitive layer pattern to form a second photosensitive layer pattern;
D-4) etching the second conductive layer by using the second photosensitive layer pattern as an etching mask to remove the second photosensitive layer of the connection portion between the source electrode and the drain electrode; and
D-5) removing the second photosensitive layer pattern.

33. The manufacturing method of claim 32, wherein the first conductive layer and the second conductive layer disposed over the gate electrode have a smaller size than that of the gate electrode in the step of D-2).

34. The manufacturing method of claim 33, wherein the first hole has a smaller size than that of the gate electrode and a larger size than that of the first conductive layer and the second conductive layer disposed over the gate electrode, and the first hole is disposed over the gate electrode in the step of E).

35. The manufacturing method of claim 34, wherein the step of E) includes forming a second hole exposing a portion of the drain electrode, the step of I) includes forming a hole aligned with the second hole, and the pixel electrode is connected to the drain electrode through the second hole and the hole.

36. The manufacturing method of claim 34, further comprising
G-1) etching the second conductive layer by using the bank as an etching mask to remove the second conductive layer exposed through the first hole between the step of G) and the step of H).

37. The manufacturing method of claim 36, wherein the step of D) includes forming contact assistants including the first conductive layer and the second conductive layer and connected to an end portion of the gate line, and the step of G-1) includes removing the second conductive layer of the contact assistants.

38. The manufacturing method of claim 30, wherein the first hole has a smaller size than that of the gate electrode and a larger size than that of the first conductive layer and the second conductive layer disposed over the gate electrode, and the first hole is disposed over the gate electrode in the step of E).

39. The manufacturing method of claim 30, further comprising
G-1) etching the second conductive layer by using the bank as an etching mask to remove the second conductive layer exposed through the first hole between the step of G) and the step of H).

40. The manufacturing method of claim 30, wherein the step of D) includes forming contact assistants including the first conductive layer and the second conductive layer and connected to an end portion of the gate line, and the step of G-1) includes removing the second conductive layer of the contact assistants.

41. A flat panel display, comprising:
a thin film transistor array panel;
a common electrode panel facing the thin film transistor array panel; and
electrophoretic particles disposed between the organic thin film transistor array panel and the common electrode panel,
wherein the thin film transistor array panel comprises
a substrate,
a gate line formed on the substrate, extending in a first direction, and including a gate electrode,
a gate insulation layer formed on the gate line and containing fluorine in a portion thereof,
a data line formed on the gate insulation layer, extending in a second direction to cross the gate line, and including a source electrode,
a drain electrode separated from the data line and facing the source electrode,
a bank including a first hole exposing the source electrode and the drain electrode and disposed on the source electrode and the drain electrode,
a semiconductor formed in the first hole and connected to the source electrode and the drain electrode to form a channel of a thin film transistor,
a passivation layer covering the bank and the semiconductor, and
a pixel electrode formed on the passivation layer and connected to the drain electrode.

42. The flat panel display of claim 41, wherein the portion of the gate insulation layer containing the fluorine has a ring planar shape formed along with the inner edge of the first hole.

43. The flat panel display of claim 41, wherein the bank contains the fluorine by being subjected to a plasma treatment.

44. The flat panel display of claim 41, wherein the data line includes a lower layer including a transparent conductive oxide and an upper layer including a metal, portions of the source electrode and drain electrode disposed in the first hole are composed of the lower layer, and remaining portions of the source electrode and drain electrode are composed of the upper layer.

45. The flat panel display of claim 44, wherein the first hole has a smaller area than that of the gate electrode and is disposed over the gate electrode.

46. The flat panel display of claim 45, wherein the pixel electrode covers the semiconductor.

47. The flat panel display of claim 46, wherein the bank further has a second hole exposing a portion of the drain electrode, and the pixel electrode is connected to the drain electrode through the second hole.

48. The flat panel display of claim 41, wherein the first hole has a smaller area than that of the gate electrode and is disposed over the gate electrode.

49. The flat panel display of claim 41, wherein the pixel electrode covers the semiconductor.
